(19) United States
(12) Patent Application Publication
(10) Pub. No.: US 2026/0107508 A1
(43) Pub. Date: Apr. 16, 2026

(54) Passivation and Isolation Techniques for Epitaxial Source/Drains of Multigate Devices

(71) Applicant: Taiwan Semiconductor Manufacturing Company, Ltd., Hsin-Chu (TW)

(72) Inventors: Sharon CHIU, Hsinchu (TW); Chun-Yang LU, Taoyuan City (TW); Liang-Yin CHEN, Hsinchu City (TW)

(21) Appl. No.: 18/915,040

(22) Filed: Oct. 14, 2024

(51) Int. Cl. H01L 29/417; H01L 21/02; H01L 21/3115; H01L 21/32; H01L 27/092

(52) U.S. Cl. CPC H10D 30/6729; H10D 84/85; H10P 14/61; H10P 14/6322; H10P 30/40

(57) ABSTRACT

Multigate devices having bottom insulation and methods of fabrication thereof are disclosed. An exemplary method includes forming a first source/drain recess in a first device region, forming a second source/drain recess in a second device region, forming a first source/drain structure in the first source/drain recess, and forming a second source/drain structure in the second source/drain recess. Forming the second source/drain structure includes forming an insulator layer in the second source/drain recess, forming a mask over the first source/drain structure after performing a first nitrogen thermal treatment on the insulator layer, and forming a doped semiconductor layer over the insulator layer after performing a second nitrogen thermal treatment on the mask. The first nitrogen thermal treatment may increase a thickness and/or reduce an etch rate of the insulator layer. The first device region may be a p-type transistor region, and the second device region may be an n-type transistor region.

### BACKGROUND

Recently, multigate devices, which have gates that extend, partially or fully, around a channel to provide access to the channel on at least two sides, have been introduced to improve gate control. Exemplary multigate devices include fin-like field effect transistors (FinFETs) and gate-all around (GAA) transistors, such as nanowire transistors. Multigate devices enable aggressive scaling down of integrated circuit (IC) technologies, maintaining gate control, and mitigating short-channel effects (SCEs), while seamlessly integrating with conventional IC manufacturing processes. As multigate devices continue to scale, advanced techniques are needed for optimizing multigate device reliability and/or performance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating source/drain structures having bottom insulation, in portion or entirety, according to various aspects of the present disclosure.

FIGS. 2A-2I are cross-sectional views of a device, in portion or entirety, at various fabrication stages of the method in FIG. 1, according to various aspects of the present disclosure.

FIGS. 3A-3F are perspective views of a device, in portion or entirety, at various fabrication stages of the method in FIG. 1, according to various aspects of the present disclosure.

FIG. 4 provides cross-sectional views of a source/drain structure, in portion or entirety, having an untreated bottom insulation layer and a treated bottom insulation layer, according to various aspects of the present disclosure.

### DETAILED DESCRIPTION

The present disclosure relates generally to multigate devices and methods of fabrication thereof, and more particularly, to leakage current reduction for multigate devices.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for case of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multigate devices include a gate structure that extends, partially or fully, around a channel region to provide access to a channel region on at least two sides. One such multigate device is the gate-all around (GAA) device, which includes channel layers (regions) that are vertically or horizontally stacked and suspended in a manner over a substrate that allows a gate stack to wrap around (or surround) and engage the channel layers. The channel layers extend between a source region and a drain region (e.g., epitaxial source/drains), and voltage can be applied to the gate stack, the source region, and/or the drain region to control a flow of current between the source region and the drain region. GAA devices can significantly increase contact area between the gate stack and the channel regions, which has been observed to decrease subthreshold swing (SS), decrease short channel effects (SCEs), increase drive current, and/or improve channel control compared to other multigate devices, such as FinFETs.

However, leakage current of GAA devices has arisen as a significant challenge as integrated circuit (IC) technology nodes scale (i.e., by increasing device density (i.e., the number of interconnected devices in a given chip area) and/or decreasing geometry size (i.e., dimensions and/or sizes of device features and/or spacings therebetween)). For example, a parasitic transistor can form between the gate stack, an elevated portion of the substrate (over which the channel layers and the gate stack are disposed), and the epitaxial source/drains, and current may undesirably flow/leak through the elevated portion of the substrate between the epitaxial source/drains. Since the gate stack wraps the elevated portion of the substrate in a conventional GAA device as opposed to surrounding it like the channel layers, the gate stack's control of the off-state leakage current in the elevated portion of the substrate is limited to three sides (e.g., tri-gate control), which has proved insufficient as IC technology nodes scale and has been observed to induce and/or exacerbate drain-induced-barrier-lowering (DIBL) in GAA devices.

The present disclosure thus proposes a bottom isolation technique (which can also be referred to as a substrate isolation technique and/or a mesa isolation technique) that improves leakage current reduction through an underlying substrate (e.g., mesa thereof), and a passivation technique that reduces source/drain loss during fabrication of source/drain structures of different type transistors. The disclosed substrate isolation technique implements a nitrogen thermal treatment to improve quality of a bottom source/drain insulator layer, and the disclosed passivation technique implements a nitrogen thermal treatment to improve quality of a source/drain mask. The nitrogen-treated bottom source/drain insulator layer is provided with a thickness of at least 3 nm and/or a more uniform thickness, both of which may improve bottom source/drain isolation. The nitrogen-treated bottom source/drain insulator layer is also provided with a reduced etch rate to a given etchant, thereby reducing its removal during subsequent processing. The nitrogen-treated source/drain mask is provided with a greater density and/or a reduced etch rate to a given etchant, thereby reducing its removal during subsequent processing and thus improving protection of one type of source/drain structure while forming another type of source/drain structure. In some embodiments, the disclosed substrate isolation technique further implements a silicon implantation process to improve the quality of the bottom source/drain insulator layer. The silicon-treated bottom source/drain insulator layer may be provided with a greater thickness and/or a reduced etch rate. The disclosed bottom source/drain isolation treatment and the disclosed passivation treatment are seamlessly and easily integrated into existing multigate device fabrication processes. Details of the proposed bottom source/drain isolation technique and source/drain passivation technique are described further below. From the following description, it may be seen that multigate devices described in the present disclosure offer advantages over conventional multigate devices. It is understood, however, that other embodiments may offer additional advantages, and not all advantages are necessarily disclosed herein, and that no particular advantage is required for all embodiments.

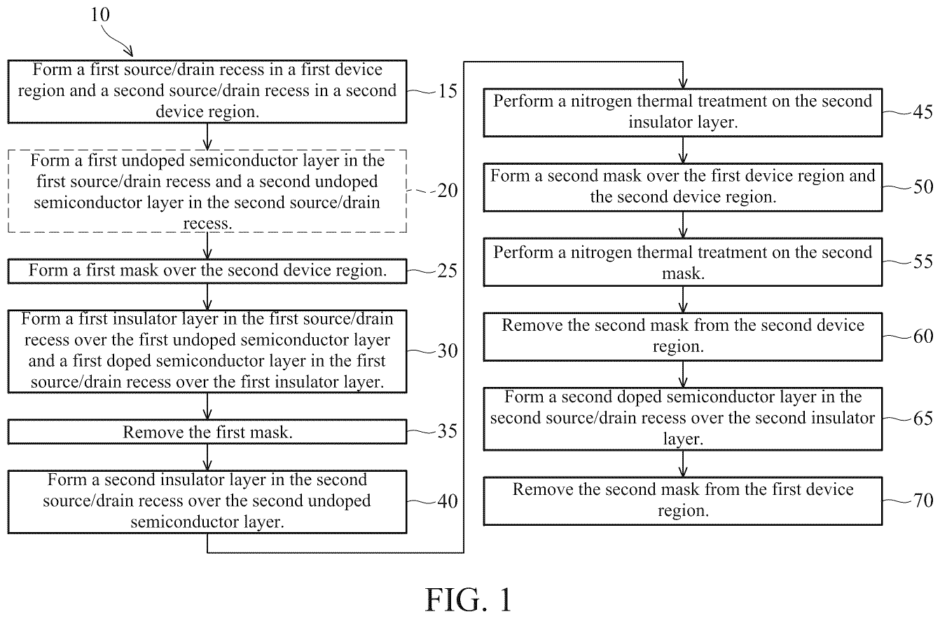

FIG. 1 is a flow chart of a method 10 for fabricating source/drain structures having bottom insulation, in portion or entirety, according to various aspects of the present disclosure. At block 15, method 10 includes forming a first source/drain recess in a first device region and a second source/drain recess in a second device region. In some embodiments, the first device region is a p-type transistor region, and the second device region is an n-type device region. At block 20, method 10 may include forming a first undoped semiconductor layer in the first source/drain recess and a second undoped semiconductor layer in the second source/drain recess. The first undoped semiconductor layer and the second undoped semiconductor layer may be formed at the same time. At block 25, block 30, and block 35, method 10 includes forming a first mask over the second device region, forming a first insulator layer in the first source/drain recess over the first undoped semiconductor layer, forming a first doped semiconductor layer in the first source/drain recess over the first insulator layer, and removing the first mask. In some embodiments, the first doped semiconductor layer is a p-type doped semiconductor layer, such as a boron-doped silicon germanium layer. In some embodiments, the first insulator layer is a nitride layer. In some embodiments, processing associated with block 25, block 30, and block 35 may be performed after processing associated with blocks 40-70.

At block 40 and block 45, method 10 includes forming a second insulator layer in the second source/drain recess over the second undoped semiconductor layer and performing a nitrogen thermal treatment on the second insulator layer. In some embodiments, the second insulator layer is a nitride layer, such as a silicon nitride layer. In some embodiments, the nitrogen thermal treatment is an anneal process performed in a nitrogen-containing ambient, such as an N₂ anneal. In some embodiments, the nitrogen thermal treatment increases a thickness of the second insulator layer. In some embodiments, the nitrogen thermal treatment modifies a composition of the second insulator layer, which may increase its resistance to a given etchant (e.g., by reducing its etch rate to the given etchant). In some embodiments, the first device region is masked when forming the second insulator layer and/or performing the nitrogen thermal treatment on the second insulator layer. In some embodiments, the first device region is not masked when forming the second insulator layer and/or performing the nitrogen thermal treatment on the second insulator layer, such that a second insulator layer may be formed over the first doped semiconductor layer. A thickness of the second insulator layer in the first device region may also be increased by the nitrogen thermal treatment. In some embodiments, method 10 may include performing a silicon implantation process on the second insulator layer before or after performing the nitrogen thermal treatment. In some embodiments, the silicon implantation process increases a thickness of the second insulator layer. In some embodiments, the silicon implantation process modifies a composition of the second insulator layer, which may increase its resistance to a given etchant (e.g., by reducing its etch rate to the given etchant).

At block 50, block 55, and block 60, method 10 includes forming a second mask over the first device region and the second device region, removing the second mask from the second device region, and perform a nitrogen thermal treatment on the second mask. In some embodiments, the second mask is a metal oxide layer, such as an aluminum oxide layer. In some embodiments, the nitrogen thermal treatment is an anneal process performed in a nitrogen-containing ambient, such as an N₂ anneal. In some embodiments, the nitrogen thermal treatment modifies a composition of the second mask (e.g., the nitrogen thermal treatment may densify the second mask), which may increase its resistance to a given etchant (e.g., by reducing its etch rate to the given etchant). At block 65, method 10 includes forming a second doped semiconductor layer in the second source/drain recess over the second insulator layer. In some embodiments, the second doped semiconductor layer is an n-type doped semiconductor layer, such as a phosphorus-doped silicon layer. In some embodiments, method 10 includes performing a pre-clean process before forming the second doped semiconductor layer over the second insulator layer. At block 70, method 10 includes removing the second mask from the first device region. Additional processing is contemplated by the present disclosure. Additional steps may be provided before, during, and after method 10, and some of the steps described may be moved, replaced, or eliminated for additional embodiments of method 10. The discussion that follows illustrates devices having source/drain structures fabricated according to method 10.

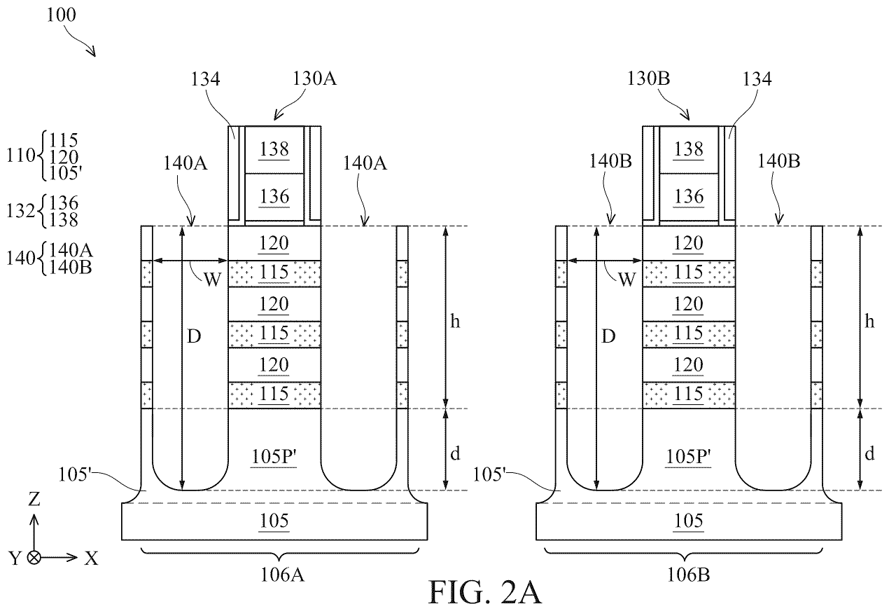

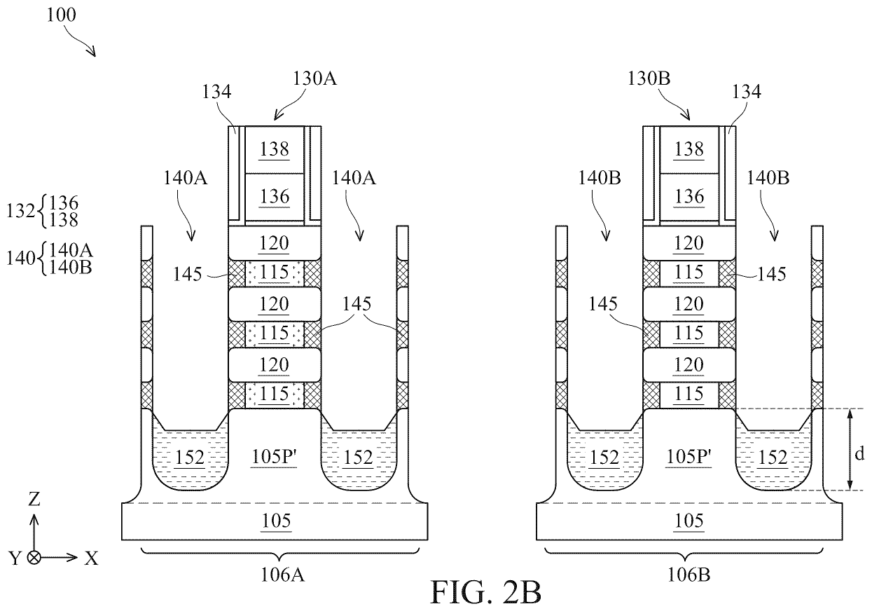

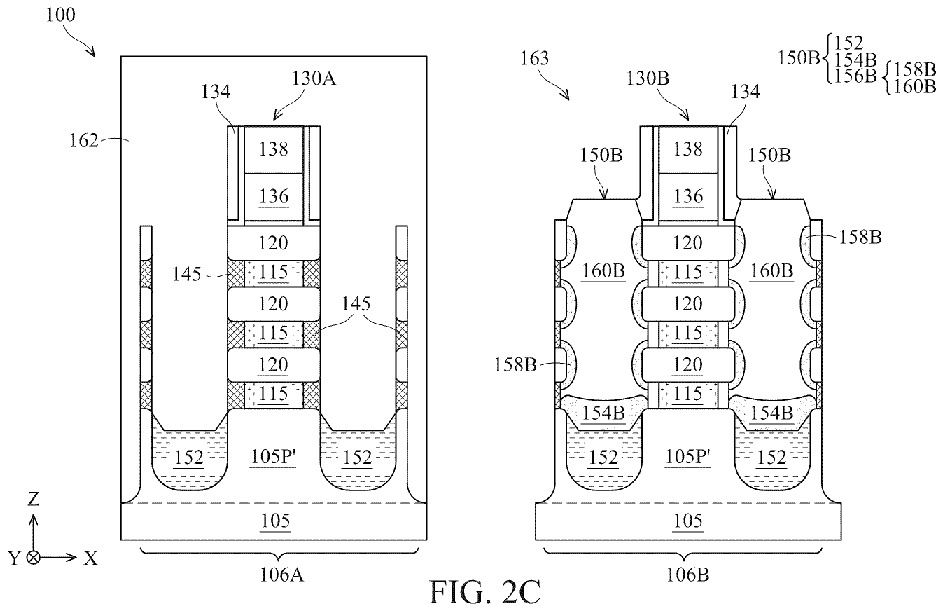

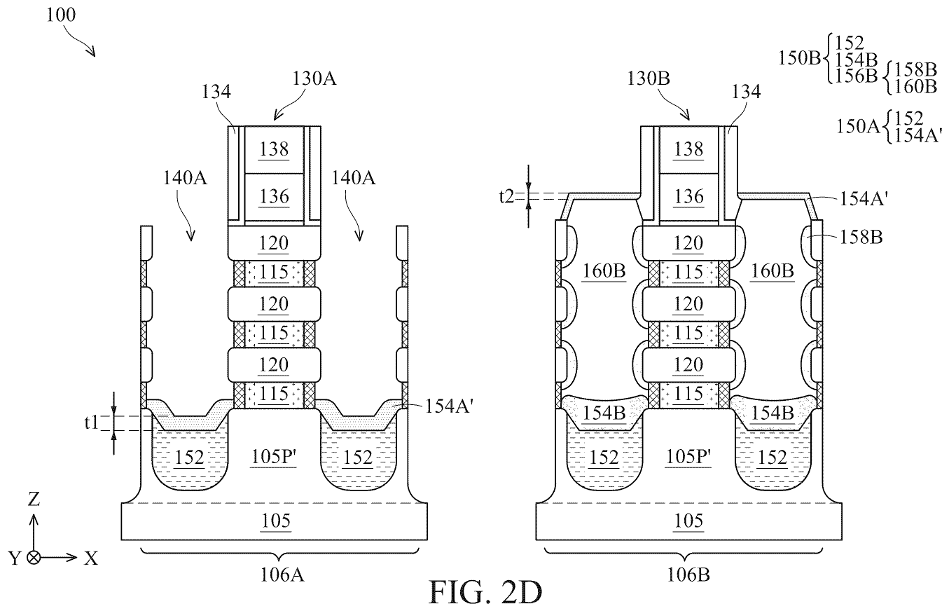

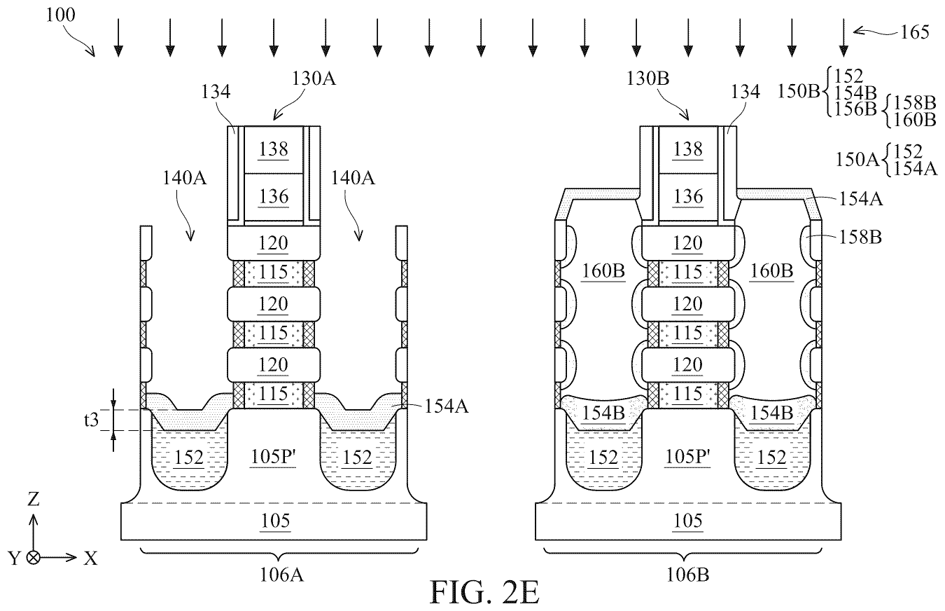

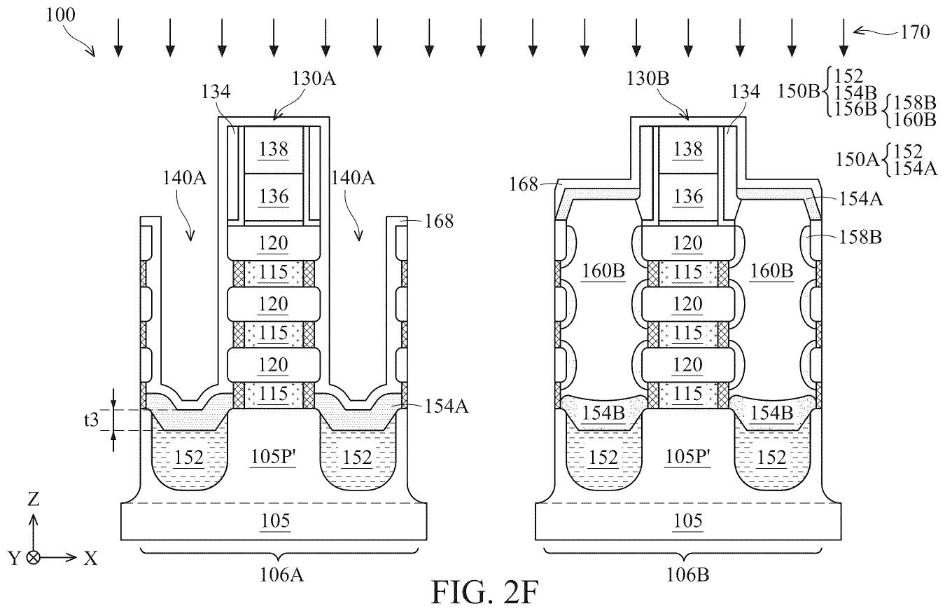

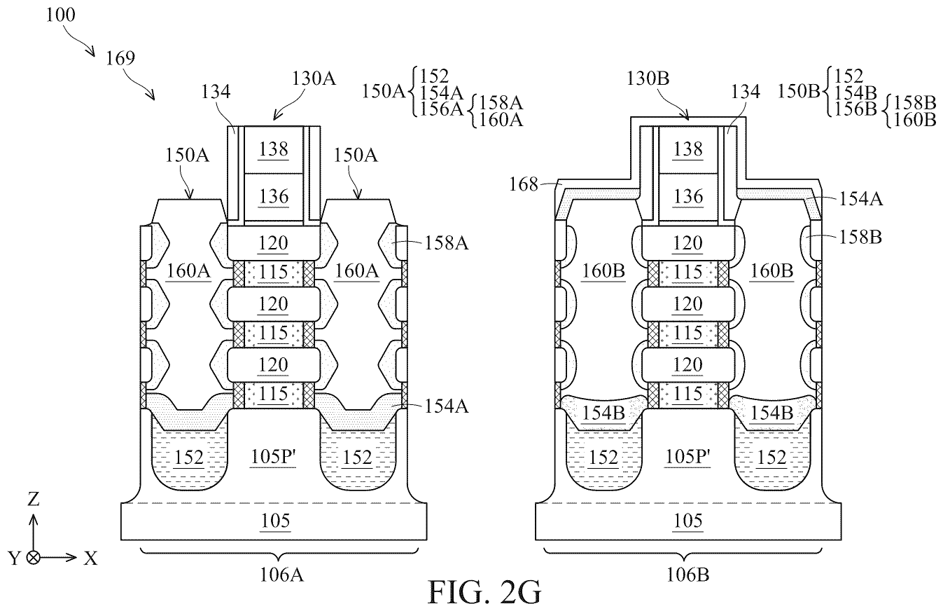

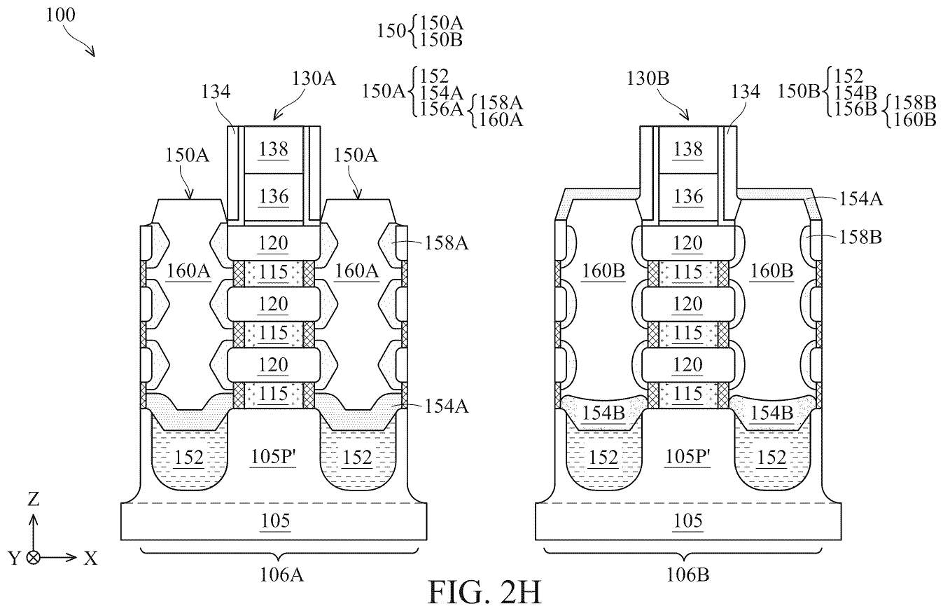

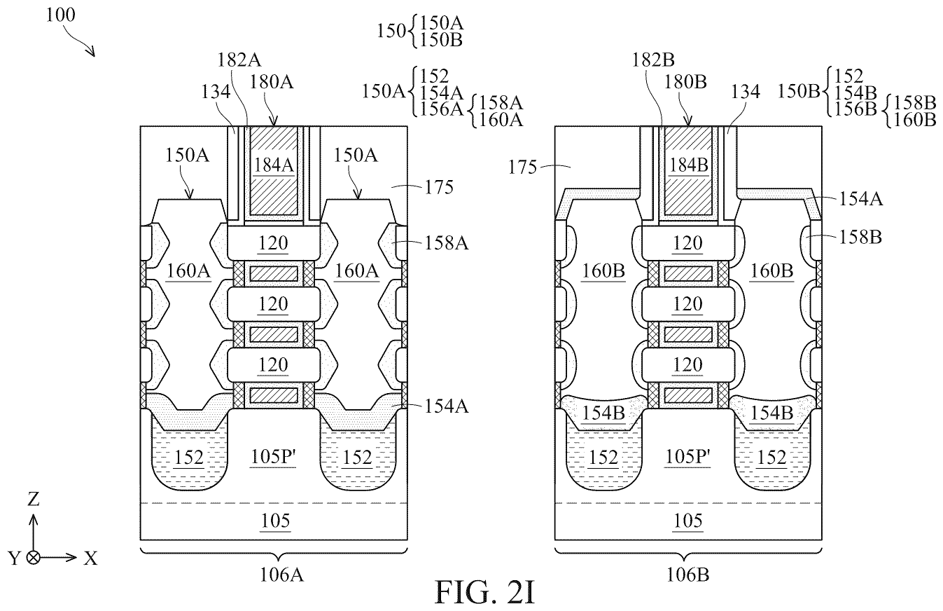

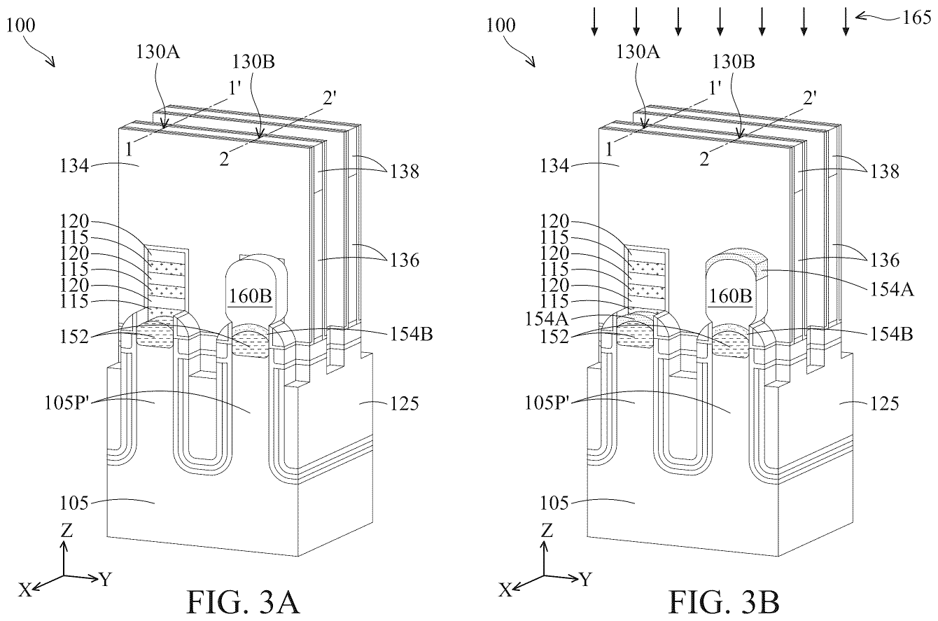

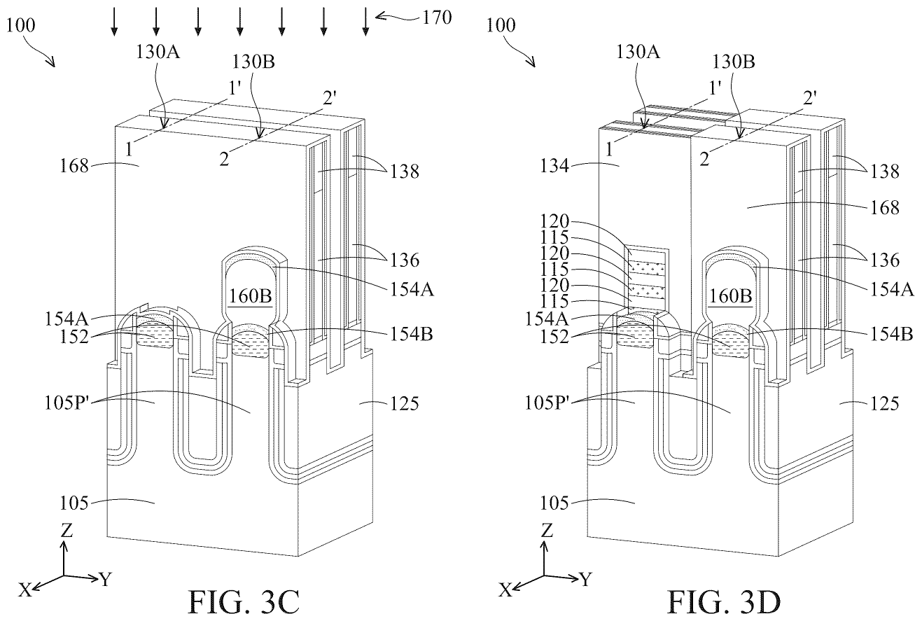

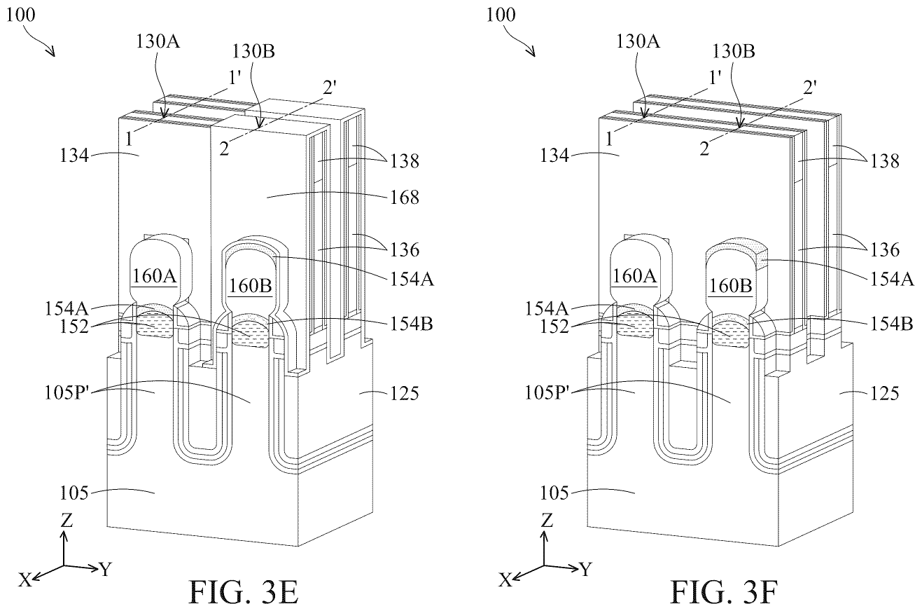

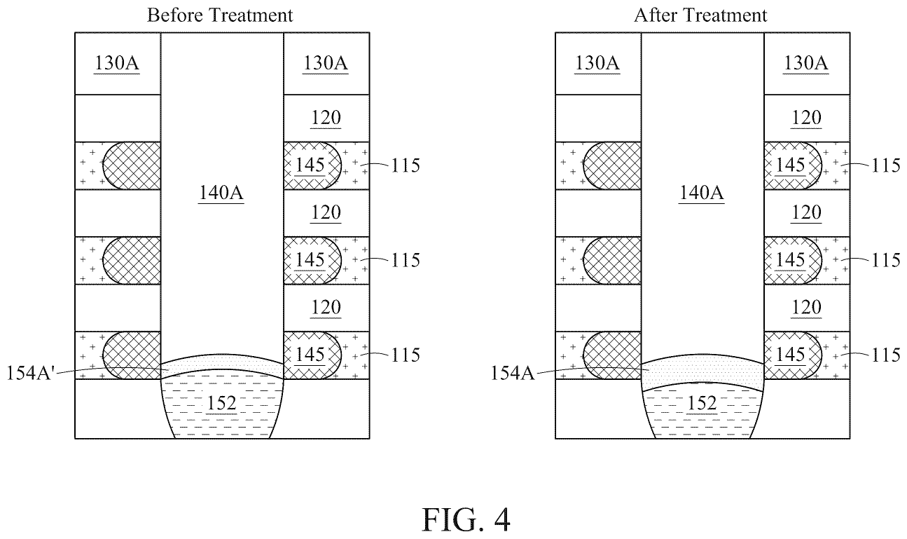

FIGS. 2A-2I are cross-sectional views of a device 100, in portion or entirety, at various fabrication stages (such as those associated with method 10 in FIG. 1) according to various aspects of the present disclosure. FIGS. 3A-3F are perspective views of a portion of device 100, in portion or entirety, at various fabrication stages (such as those associated with method 10 in FIG. 1) according to various aspects of the present disclosure. FIG. 3A corresponds with the fabrication stage at FIG. 2C (where FIG. 2C is taken along line 1-1′ and 2-2′ of FIG. 3A to provide cross-sectional views of device region 102A and device region 102B, respectively). FIG. 3B corresponds with the fabrication stage at FIG. 2E (where FIG. 2E is taken along line 1-1′ and 2-2′ of FIG. 3B to provide cross-sectional views of device region 102A and device region 102B, respectively). FIG. 3C corresponds with the fabrication stage at FIG. 2F (where FIG. 2F is taken along line 1-1′ and 2-2′ of FIG. 3C to provide cross-sectional views of device region 102A and device region 102B, respectively). FIG. 3D and FIG. 3E correspond with the fabrication stage at FIG. 2G (where FIG. 2G is taken along line 1-1′ and 2-2′ of FIG. 3E to provide cross-sectional views of device region 102A and device region 102B, respectively). FIG. 3F corresponds with the fabrication stage at FIG. 2H (where FIG. 2H is taken along line 1-1′ and 2-2′ of FIG. 3F to provide cross-sectional views of device region 102A and device region 102B, respectively). FIG. 4 provides a cross-sectional view of a source/drain structure, in portion or entirety, having an untreated bottom insulation layer, and a cross-sectional view of the source/drain structure, in portion or entirety, having a treated bottom insulation layer (e.g., treated as described herein with nitrogen and/or silicon), according to various aspects of the present disclosure. FIGS. 2A-2I, FIGS. 3A-3F, and FIG. 4 are discussed concurrently herein for ease of description and understanding. FIGS. 2A-2I, FIGS. 3A-3F, and FIG. 4 have been simplified for the sake of clarity to better understand the inventive concepts of the present disclosure. Additional features may be added in device 100, and some of the features described below may be replaced, modified, or eliminated in other embodiments of device 100.

After undergoing processing associated with FIGS. 2A-2I, device 100 may include at least one GAA transistor (i.e., a transistor having a gate that at least partially surrounds a suspended channel(s) (for example, a nanowire(s), a nanosheet(s), a nanobar(s), or the like) that extends between source/drains). For example, device 100 may be processed to form a first transistor in a device region 102A and a second transistor in a device region 102B. In the depicted embodiment, device 100 is processed to form an n-type transistor in device region 102A and a p-type transistor in device region 102B. In such embodiments, device 100 may include a complementary metal-oxide semiconductor (CMOS) transistor (e.g., an n-type transistor and a p-type transistor). In some embodiments, the first transistor and the second transistor are both n-type transistors or both p-type transistors. Device 100 may be included in a microprocessor, a memory, other IC device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof.

Referring to FIG. 2A, fabrication of device 100 may include forming and/or receiving a device precursor that includes a substrate 105, a multilayer stack 110 (including, e.g., a mesa 105′, sacrificial layers 115, and semiconductor layers 120), substrate isolation structures 125, a gate structure 130A and a gate structure 130B. In the depicted embodiment, gate structure 130A and gate structure 130B each include a respective dummy gate stack 132 and respective gate spacers 134, and each dummy gate stack 132 may include a respective dummy gate 136 and a respective hard mask 138. After forming/receiving the device precursor, fabrication of device 100 may include forming source/drain recesses 140A in device region 102A and source/drain recesses 140B in device region 102B, as described further below. Before forming source/drain recesses 140A, 140B, multilayer stack 110 extends continuously and substantially along an x-direction, having a length along the x-direction, a width along a y-direction, and a height along a z-direction. Multilayer stack 110 may be referred to as a fin, a fin structure, a fin element, an active fin region, an active region, etc. In some embodiments, mesa 105′ is a patterned, projecting portion and/or extension of substrate 105, and mesa 105′ may be referred to as a substrate extension, a substrate fin portion, a fin portion, an etched substrate portion, etc.

Substrate 105 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and mesa 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. The doped regions may be formed on and/or in substrate 105, for example, providing a p-well structure, an n-well structure, a dual-well structure, a raised structure, other suitable structure, or combinations thereof. In some embodiments, substrate 105 and/or mesa 105′, and semiconductor layers thereover, may include an n-well and/or a p-well. For example, mesa 105′ may include a p-well in device region 102A, such as where an n-type transistor is formed therein, and an n-well in device region 102B, such as where a p-type transistor is formed therein, or vice versa.

Sacrificial layers 115 and semiconductor layers 120 are stacked vertically (e.g., along the z-direction) in an interleaving and/or alternating configuration from a top of substrate 105. A composition of sacrificial layers 115 is different than a composition of semiconductor layers 120 to achieve etch selectivity. For example, sacrificial layers 115 and semiconductor layers 120 include different materials, constituent atomic percentages, constituent weight percentages, other characteristics, or combinations thereof to achieve etch selectivity. In some embodiments, sacrificial layers 115 include silicon germanium, semiconductor layers 120 include silicon, and an etch rate of semiconductor layers 120 is different than an etch rate of sacrificial layers 115 to a given etchant. In some embodiments, sacrificial layers 115 and semiconductor layers 120 include the same material but with different constituent atomic percentages. For example, sacrificial layers 115 and semiconductor layers 120 may include silicon germanium, and sacrificial layers 115 and semiconductor layers 120 may have different germanium atomic percentages to provide etch selectivity. Sacrificial layers 115 and semiconductor layers 120 may include any combination of materials that provides desired etching selectivity, desired oxidation rate differences, and/or desired performance characteristics (e.g., materials that maximize current flow), including any of the materials disclosed herein.

Semiconductor layers 120 or portions thereof may form channels of transistors of device 100. In FIG. 2A, multilayer stack 110 includes three sacrificial layers 115 and three semiconductor layers 120. Multilayer stack 110 thus includes three semiconductor layer pairs disposed over substrate 105, each of which has a respective sacrificial layer 115 and a respective semiconductor layer 120. After processing of multilayer stack 110, this configuration may result in transistors having three channels. However, in some embodiments, multilayer stack 110 includes different numbers of semiconductor layers 120 depending, for example, on a number of channels desired for transistors of and/or design requirements of device 100. For example, multilayer stack 110 may include two to six semiconductor layer pairs, each of which may has a respective sacrificial layer 115 and a respective semiconductor layer 120.

Substrate isolation structures 125 may be formed adjacent to and around a lower portion of multilayer stack 110 (e.g., mesa 105′ thereof), and multilayer stack 110 may be separated from other multilayer stacks and/or other device regions by substrate isolation structures 125. Substrate isolation structures 125 may electrically isolate an active device region (e.g., multilayer stack 110) from other device regions, such as another multilayer stack. Substrate isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 125 may have a multilayer structure. For example, substrate isolation structures 125 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 125 may include a bulk dielectric over a doped liner, such as a boron silicate glass (BSG) liner and/or a phosphosilicate glass (PSG) liner. Dimensions and/or characteristics of substrate isolation structures 125 may be configured to provide shallow trench isolation (STI) structures, deep trench isolation (DTI) structures, local oxidation of silicon (LOCOS) structures, other suitable isolation structures, or combinations thereof.

Gate structure 130A and gate structure 130B may be formed over channel regions (C) of multilayer stack 110 and between respective source/drain regions (S/D) of multilayer stack 110. Dummy gate stacks 132 extend lengthwise along a direction different than (e.g., orthogonal to) the lengthwise direction of multilayer stack 110. For example, dummy gate stacks 132 extend along the y-direction, having a length along the y-direction, a width along the x-direction, and a height along the z-direction. Dummy gate stacks 132 may extend substantially parallel to one another. In FIG. 2A (e.g., the X-Z plane), dummy gate stacks 132 are disposed on top of respective channel regions, and dummy gate stacks 132 are disposed between respective source/drain regions. In a cross-sectional view along a Y-Z plane, dummy gate stacks 132 may wrap respective channel regions (e.g., be disposed over the top and sidewalls thereof), and dummy gate stacks 132 may be disposed over tops of substrate isolation structures 125.

Dummy gates 136 may include a dummy gate dielectric and a dummy gate electrode. The dummy gate dielectric includes a dielectric material, such as silicon oxide and/or other suitable dielectric material. The dummy gate electrode includes a suitable dummy gate material, such as polysilicon. Hard masks 138 may be configured to protect dummy gates 136 during processing. For example, hard masks 138 may include a material that is resistant to an etching process, such as a source/drain etch, to protect dummy gates 136 therefrom. In some embodiments, hard masks 138 have a multilayer structure, such as a first mask layer disposed over a second mask layer. Hard masks 138 include any suitable hard mask material.

Gate spacers 134 are formed adjacent to and along sidewalls of dummy gate stacks 132. Gate spacers 134 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 134 have a multilayer structure, such as two or more dielectric layers having different compositions. In some embodiments, gate spacers 134 include more than one set of spacers, such as seal spacers, offset spacers, sacrificial spacers, dummy spacers, main spacers, or combinations thereof. In such embodiments, the various sets of spacers may have different compositions.

In FIG. 2A, a source/drain etch removes portions of multilayer stack 110 that are not covered by gate structure 130A and gate structure 130B, thereby forming source/drain recesses (trenches) 140A and source/drain recesses 140B (collectively referred to as source/drain recesses 140). For example, the source/drain etch removes semiconductor layers 120 and sacrificial layers 115 in source/drain regions of multilayer stack 110, thereby exposing mesa 105′. The source/drain etch may further remove some, but not all, of mesa 105′ in source/drain regions of multilayer stack 110, such that source/drain recesses 140 extend into but not through mesa 105′. After the source/drain etch, sacrificial layers 115, semiconductor layers 120, and projecting portions formed from mesa 105′ (referred to hereafter as mesas 105P′) remain in channel regions of multilayer stack 110, and source/drain recesses 140 expose sidewalls of sacrificial layers 115, semiconductor layers 120, and mesas 105P′ remaining in channel regions. In the depicted embodiment, source/drain recesses 140 extend through multilayer stack 110 to a depth d in mesa 105′, source/drain recesses 140 have a depth D between the top of multilayer stack 110 and bottoms of source/drain recesses 140, and source/drain recesses 140 have a width W. Depth D may be a sum of a height h of multilayer stack 110 and depth d of source/drain recesses 140.

The source/drain etch is a dry etch, a wet etch, other suitable etch, or combinations thereof. In some embodiments, the source/drain etch is a multistep etch process, which may alternate etchants to remove sacrificial layers 115 and semiconductor layers 120 separately and alternately. In some embodiments, source/drain etch parameters (e.g., etchant thereof) are tuned to selectively remove semiconductor materials (e.g., semiconductor layers 120, sacrificial layers 115, and mesa 105′) with negligible (to no) removal of dielectric materials (e.g., hard masks 138, gate spacers 134, substrate isolation structures 125, etc.).

Referring to FIG. 2B, inner spacers 145 may be formed under gate spacers 134 along sidewalls of sacrificial layers 115. Inner spacers 145 may replace edges/ends of sacrificial layers 115, which may be disposed under gate spacers 134. In the depicted embodiment, remainders of sacrificial layers 115 are disposed between respective inner spacers 145 along the x-direction, top inner spacers 145 and middle inner spacers 145 are disposed between ends of respective semiconductor layers 120 along the z-direction, and bottom inner spacers 145 are disposed between ends of bottom semiconductor layers 120 and mesas 105P′ along the z-direction.

Forming inner spacers 145 may include a first etching process, a deposition process, and a second etching process. The first etching process may selectively etch sacrificial layers 115 with negligible (to no) etching of semiconductor layers 120, mesas 105P′, dummy gate stacks 132 (e.g., hard masks 138 thereof), gate spacers 134, substrate isolation structures 125, or combinations thereof. The first etching process may be configured to laterally etch (e.g., along the x-direction and/or the y-direction) sacrificial layers 115 to reduce their lengths along the x-direction, such that lengths of sacrificial layers 115 are less than lengths of semiconductor layers 120. The first etching process may form inner spacer recesses between semiconductor layers 120 and between semiconductor layers 120 and mesas 105P′. In some embodiments, the inner spacer recesses laterally extend (e.g., along the x-direction) under dummy gate stacks 132. The first etching process is a dry etch, a wet etch, other suitable etch, or combinations thereof. In some embodiments, the first etching process is an anisotropic etch.

The deposition process forms an inner spacer layer over device 100 that may fill the inner spacer recesses. In some embodiments, a single deposition process is performed to form an inner spacer layer that fills the inner spacer recesses. In some embodiments, inner spacers 145 have multilayer structures. For example, more than one deposition process may be performed to form the inner spacer layer, such as a first deposition process to form a first inner spacer sublayer and a second deposition process to form a second inner spacer sublayer. The first inner spacer sublayer partially fills the inner spacer recesses, and the second inner spacer sublayer partially or completely fills the inner spacer recesses. A composition and/or a material of the first inner spacer sublayer may be the same or different than a composition and/or a material of the second inner spacer sublayer. In some embodiments, inner spacers 145 include air gaps (voids).

The second etching process may selectively etch the inner spacer layer with negligible (to no) etching of semiconductor layers 120, mesas 105P′, dummy gate stacks 132 (e.g., hard masks 138 thereof), gate spacers 134, substrate isolation structures 125, or combinations thereof. Remainders of the inner spacer layer provide inner spacers 145, such as depicted. To achieve desired etching selectivity, the inner spacer layer (and thus inner spacers 145) have a composition different than compositions of semiconductor layers 120, mesas 105P′, dummy gate stacks 132, gate spacers 134, substrate isolation structures 125, or combinations thereof. In some embodiments, the inner spacer layer includes a dielectric material that includes silicon, oxygen, carbon, nitrogen, other suitable dielectric constituent, or combinations thereof. For example, the inner spacer layer may be a silicon carbide layer, a silicon carbonitride layer, a silicon oxycarbonitride layer, a silicon oxycarbide layer, or combinations thereof. The second etching process is a dry etch, a wet etch, other suitable etch, or combinations thereof.

Referring to FIGS. 2B-2H, source/drain structures 150A are formed in source/drain recesses 140A, and source/drain structures 150B are formed in source/drain recesses 140B. Source/drain structures 150A and source/drain structures 150B may be referred to collectively as source/drain structures 150 herein. Source/drain structures 150A may include a respective undoped semiconductor layer 152, a respective insulator layer 154A, and a respective doped semiconductor layer 156A. In some embodiments, doped semiconductor layers 156A have a multilayer structure, such as a doped semiconductor layer 158A and a doped semiconductor layer 160A. Source/drain structures 150B may include a respective undoped semiconductor layer 152, a respective insulator layer 154B, and a respective doped semiconductor layer 156B. In some embodiments, doped semiconductor layers 156B have a multilayer structure, such as a doped semiconductor layer 158B and a doped semiconductor layer 160B. In the depicted embodiment, where device region 102A is an n-type transistor region and device region 102B is a p-type transistor region, source/drain structures 150A form source/drains of n-type transistors, and source/drain structures 150B form source/drains of p-type transistors. In such embodiments, source/drain structures 150A may include semiconductor material(s) doped with n-type dopant (e.g., carbon, phosphorous, arsenic, antimony, other n-type dopant, or combinations thereof), and source/drain structures 150B may include semiconductor material(s) doped with p-type dopant (e.g., boron, gallium, other p-type dopant, or combinations thereof). As further described below, the disclosed source/drain structure fabrication process implements treatment processes, such as nitrogen thermal treatments (e.g., nitrogen-containing anneals), to improve bottom source/drain insulation, thereby reducing leakage current, and/or improve passivation during source/drain patterning, thereby reducing unintentional loss of source/drain structures.

Referring again to FIG. 2B, undoped semiconductor layers 152 may be formed in source/drain recesses 140A, such as in bottoms thereof, and source/drain recesses 140B, such as in bottoms thereof. In the depicted embodiment, undoped semiconductor layers 152 are formed simultaneously in device region 102A and device region 102B. In some embodiments, undoped semiconductor layers 152 are formed in device region 102A before or after forming undoped semiconductor layers 152 in device region 102B. Undoped semiconductor layers 152 are dopant-free (i.e., substantially free of n-type dopants and p-type dopants). For example, no intentional doping is performed when forming undoped semiconductor layers 152. Undoped semiconductor layers 152 may provide high resistance paths at bottoms of source/drain recesses 140, thereby suppressing leakage current into substrate 105. Undoped semiconductor layers 152 include silicon, germanium, silicon germanium, other suitable semiconductor materials, or combinations thereof. In some embodiments, undoped semiconductor layers 152 are dopant-free silicon layers or dopant-free silicon germanium layers. In some embodiments, semiconductor materials having dopant concentrations less than about 5×10¹⁸ cm⁻³ (e.g., about 1×10¹⁸ cm⁻³ to about 5×10¹⁸ cm⁻³) are considered undoped and/or unintentionally doped (UID).

Undoped semiconductor layers 152 are disposed on mesas 105P′ and/or mesa 105′. In the depicted embodiment, undoped semiconductor layers 152 have recessed top surfaces (e.g., concave and/or trough-shaped top surfaces), and a thickness of at least a portion of undoped semiconductor layers 152 (e.g., central portions thereof) is less than a height of mesas 105P′, such that source/drain recesses 140 still extend a depth into mesas 105P′. The depth may be given by a difference between initial depth d of source/drain recesses 140 and a minimum thickness of undoped semiconductor layers 152. In furtherance of the depicted embodiment, undoped semiconductor layers 152 have edges/end portions having a thickness that is less than or equal to the height of mesas 105P′, but greater than the minimum thickness. In such embodiments, undoped semiconductor layers 152 may not extend above tops of mesas 105P′. In some embodiments, the thickness of the edges/end portions of undoped semiconductor layers 152 is a maximum thickness thereof. The present disclosure contemplates embodiments where undoped semiconductor layers 152 completely fill bottoms of source/drain recesses 140 and/or where undoped semiconductor layers 152 extend above tops of mesas 105P′.

Undoped semiconductor layers 152 may be deposited on and/or grown from substrate 105, mesa 105′, mesas 105P′, or combinations thereof. In some embodiments, undoped semiconductor layers 152 are formed by a selective epitaxial growth (SEG) process, which may selectively deposit/grow semiconductor material (e.g., silicon) on/from exposed semiconductor surfaces. In such embodiments, undoped semiconductor layers 152 may be referred to as undoped epitaxial layers. The SEG process may use chemical vapor deposition (CVD) techniques (e.g., vapor-phase epitaxy (VPE), ultra-high vacuum CVD (UHV-CVD), low pressure CVD (LPCVD), plasma-enhanced CVD (PECVD), or the like), molecular beam epitaxy, other suitable epitaxial growth process, or combinations thereof. In some embodiments, undoped semiconductor layers 152 are formed by a bottom-up deposition process (which may be an SEG process), such that semiconductor material is deposited on mesas 105P′, mesa 105′, and/or substrate 105 (i.e., in bottoms of source/drain recesses 140) with minimal (to no) deposition of semiconductor material on semiconductor layers 120. In some embodiments, an etching process may be performed after the bottom-up deposition process to remove any semiconductor material that may have formed on semiconductor layers 120. The post-deposition etch may be a dry etch, a wet etch, other suitable etch, or combinations thereof.

Referring to FIG. 2C, fabrication of device 100 may include forming a mask 162 that covers device region 102A (e.g., an n-type transistor region), but not device region 102B (e.g., a p-type transistor region), and forming additional layers of source/drain structures 150B in device region 102B. For example, mask 162 has an opening 163 therein that overlaps device region 102B. In some embodiments, mask 162 is formed by depositing a hard mask material over device region 102A and device region 102B and performing a patterning process to remove the hard mask material from device region 102B, thereby exposing source/drain recesses 140B. The patterning process may include performing a lithography process to form a patterned resist layer that covers the hard mask material over device region 102A and exposes the hard mask material over device region 102B (e.g., the patterned resist layer has an opening therein that overlaps device region 102B) and performing an etching process to selectively remove the exposed hard mask material. A composition of mask 162 is different than compositions of source/drain structures 150A (e.g., undoped semiconductor layers 152 thereof), source/drain structures 150B (e.g., doped semiconductor layers 160B thereof), semiconductor layers 120, gate structure 130A, gate structure 130B, inner spacers 145, or combinations thereof to enable selective removal/etching therebetween. In some embodiments, mask 162 includes metal and oxygen and/or nitrogen (e.g., mask 162 is a metal oxide mask and/or a metal nitride mask). For example, mask 162 may include aluminum and oxygen and/or nitrogen, and mask 120 may be an aluminum oxide mask, an aluminum oxynitride mask, an aluminum nitride mask, or combinations thereof. In some embodiments, mask 162 is a patterned resist layer.

Insulator layers 154B may be formed in source/drain recesses 140B over undoped semiconductor layers 152 while device region 102A is covered by mask 162. Insulator layers 154B partially fill source/drain recesses 140B, and insulator layers 154B may be disposed on bottommost inner spacers 145 and/or mesas 105P′. In some embodiments, insulator layers 154B fill remainders of bottoms of source/drain recesses 140B, and insulator layers 154B are disposed at least partially above tops of mesas 105P′. Insulator layers 154B include an electrically insulating material, such as a dielectric material, that may reduce unwanted leakage current, such as current that may undesirably flow between doped semiconductor layers 156B through mesas 105P′. In some embodiments, insulator layers 154B include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. In some embodiments, insulator layers 154B include a metal-comprising dielectric material, such as a metal oxide material and/or a metal nitride material. In some embodiments, insulator layers 154B include a doped semiconductor material that includes an opposite type of dopant than doped semiconductor layers 156B. For example, in the depicted embodiment, where doped semiconductor layers 156B are portions of source/drains of p-type transistors (e.g., p-type doped semiconductor layers), insulator layers 154B may include an n-type doped semiconductor material, such as phosphorous-doped silicon.

Insulator layers 154B may be formed by depositing an insulator material over device 100 and etching the insulator material, such that remainders of the insulator material fill bottoms of source/drain recesses 140B. The as-deposited insulator material may be disposed on a top of gate structure 130B (e.g., tops of gate spacers 134 and dummy gate stack 132), sidewalls of gate structure 130B (e.g., of gate spacers 134), sidewalls of semiconductor layers 120, sidewalls of inner spacers 145, sidewalls of mesas 105P′, and tops of mesa 105′ in source/drain regions. In some embodiments, as a result of properties of a deposition process (e.g., physical vapor deposition (PVD)), a thickness of the insulator material over horizontally oriented surfaces (e.g., tops of undoped semiconductor layers 152 in source/drain regions and top of gate structure 130B) may be greater than a thickness of the insulator material over vertically oriented surfaces (e.g., sidewalls of gate structure 130B, sidewalls of semiconductor layers 120, and sidewalls of inner spacers 145). Parameters of the etching may thus be tuned to remove vertically oriented portions of the insulator material, such as that on sidewalls of gate structure 130B, sidewalls of semiconductor layers 120, and sidewalls of inner spacers 145. In such embodiments, as a result of etch loading effects, the etching may also remove horizontally oriented portions of the insulator material on top of gate structure 130B, but not (or minimally) horizontally oriented portions and/or vertically oriented portions of the insulator material in bottoms of source/drain recesses 140B, such as that disposed on undoped semiconductor layers 152 (i.e., the etching process may thin but not substantially remove such portions). In some embodiments, the as-deposited insulator material fills source/drain recesses 140B and the etching recesses the insulator material at least to bottom sacrificial layers 115 and/or bottom inner spacers 145. The etching may be a dry etch, a wet etch, other suitable etch, or combinations thereof.

Doped semiconductor layers 156B may also be formed in source/drain recesses 140B over insulator layers 154B and/or undoped semiconductor layers 152 while device region 102A is covered by mask 162. Doped semiconductor layers 156B fill remainders of source/drain recesses 140B, and doped semiconductor layers 156B are coupled to edges/end portions of semiconductor layers 120 in device region 102B. In the depicted embodiment, doped semiconductor layers 156B include doped semiconductor layers 158B and doped semiconductor layers 160B. Doped semiconductor layers 158B may be formed over semiconductor layers 120 (e.g., sidewalls and/or ends thereof) and partially fill source/drain recesses 140B, and doped semiconductor layers 160B may be formed over doped semiconductor layers 158B and/or insulator layers 154B and fill remainders of source/drain recesses 140B. Doped semiconductor layers 160B are separated from semiconductor layers 120 by doped semiconductor layers 158B, and doped semiconductor layers 160B are separated from undoped epitaxial layers 152 by insulator layers 154B. In the depicted embodiment, doped semiconductor layers 158B are discontinuous and formed of discrete and separate portions, each of which is disposed on an end of a respective semiconductor layer 120 (i.e., portions of doped semiconductor layers 158B disposed on adjacent semiconductor layers 120 are not connected to one another). In such embodiment, doped semiconductor layers 160B may wrap doped semiconductor layers 158B, and doped semiconductor layers 160B may extend to inner spacers 145. In some embodiments, one or more of the discrete, separate portions of doped semiconductor layers 158B may wrap a respective semiconductor layer 120, such that the discrete, separate portions are formed over a top and/or a bottom of the respective semiconductor layer 120. In some embodiments, the discrete, separate portions extend over and/or to inner spacers 145. In some embodiments, one or more of the discrete, separate portions of doped semiconductor layers 158B are connected. In such embodiments, doped semiconductor layers 158B may form sidewalls of source/drain structures 150B above mesas 105P′. Further, in such embodiments, doped semiconductor layers 160B may be separated from inner spacers 145 by doped semiconductor layers 158B.

Doped semiconductor layers 158B and doped semiconductor layers 160B include silicon, germanium, silicon germanium, other suitable semiconductor materials, or combinations thereof. In some embodiments, doped semiconductor layers 158B and doped semiconductor layers 160B include the same semiconductor material with different constituent concentrations. For example, doped semiconductor layers 158B and doped semiconductor layers 15608B may include silicon germanium and p-type dopant (e.g., boron and/or gallium), but different germanium concentrations and/or different p-type dopant concentrations. In some embodiments, doped semiconductor layers 158B have a smaller germanium concentration (e.g., Ge %) and/or a smaller p-type dopant concentration (e.g., B %) than doped semiconductor layers 160B, which may reduce crystalline dislocation, reduce other crystalline defects, maximize strain (and thereby enhance carrier mobility, which increases drive current), or combinations thereof. In some embodiments, a germanium concentration in doped semiconductor layers 158B is about 10% to about 20%, and a germanium concentration in doped semiconductor layers 160B is about 30% to about 60%. In some embodiments, doped semiconductor layers 158B have a p-type dopant concentration (e.g., a boron concentration) of about 1×10²⁰ cm⁻³ to about 5×10²⁰ cm⁻³, and doped semiconductor layers 160B have a p-type dopant concentration (e.g., boron concentration) of about 5×10²⁰ cm⁻³ to about 2×10²¹ cm⁻³. In such embodiments, doped semiconductor layers 160B may be referred to as heavily doped semiconductor layers, and doped semiconductor layers 158B may be referred to as lightly doped semiconductor layer. In some embodiments, doped semiconductor layers 158B and doped semiconductor layers 160B have different semiconductor materials, which may have the same or different constituent concentrations. In some embodiments, doped semiconductor layers 156B include materials and/or dopants that provide desired compressive stress in channel regions (e.g., semiconductor layers 120).

Doped semiconductor layers 158B may be deposited on and/or grown from semiconductor layers 120, and doped semiconductor layers 160B may be deposited on and/or grown from doped semiconductor layers 158B. In some embodiments, doped semiconductor layers 158B and doped semiconductor layers 160B are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of semiconductor layers 120, doped semiconductor layers 158B, or combinations thereof. Epitaxial growth/deposition conditions, such as those described herein, are tuned to selectively deposit (grow) semiconductor material (e.g., silicon germanium) on semiconductor surfaces (e.g., semiconductor layers 120 and/or doped semiconductor layers 158B) while limiting (or preventing) growth of semiconductor material from dielectric surfaces and/or non-semiconductor surfaces (e.g., inner spacers 145, dummy gate stacks 132, gate spacers 134, and/or substrate isolation structures 125). In some embodiments, doped semiconductor layers 158B and/or doped semiconductor layers 160B are doped during deposition (i.e., in-situ doping), such as by adding dopants to a source material of the SEG processes. In some embodiments, doped semiconductor layers 158B and/or doped semiconductor layers 160B are doped after deposition, such as by an ion implantation process. In some embodiments, annealing is performed to activate dopants in doped semiconductor layers 158B, doped semiconductor layers 160B, other source/drain regions, such as source/drain junction implant regions, or combinations thereof.

Referring to FIG. 3A, mask 162 may be removed after forming the additional layers of source/drain structures 150B by any suitable process, such as an etching process and/or a resist stripping process. Referring to FIGS. 2D-2H and FIGS. 3B-3F, fabrication of device 100 may include forming additional layers of source/drain structures 150A in device region 102A, such as insulator layers 154A and doped semiconductor layers 156A. Device region 102B may be exposed when forming insulator layers 154A, and device region 102B may be covered when forming doped semiconductor layers 156A, such as described herein.

Referring to FIG. 2D, FIG. 2E, and FIG. 3B, insulator layers 154A may be formed in source/drain recesses 140A over undoped semiconductor layers 152. Insulator layers 154A partially fill source/drain recesses 140A, and insulator layers 154A may be disposed on bottommost inner spacers 145 and/or mesas 105P′. In some embodiments, insulator layers 154A fill remainders of bottoms of source/drain recesses 140A, and insulator layers 154A are disposed at least partially above tops of mesas 105P′. Insulator layers 154A include an electrically insulating material, such as a dielectric material, that may reduce unwanted leakage current, such as current that may undesirably flow between doped semiconductor layers 156A through mesas 105P′. In the depicted embodiment, insulator layers 154A are nitride layers. The nitride layers may include a silicon-and-nitrogen comprising dielectric material, such as silicon nitride, silicon oxynitride, silicon oxycarbonitride, silicon carbonitride, other suitable silicon-and-nitrogen comprising dielectric material, or combinations thereof. For example, insulator layers 154A may be silicon nitride layers. In some embodiments, the nitride layers include a metal-and-nitrogen comprising dielectric material, and insulator layers 154A may be metal nitride layers.

Referring to FIG. 2D, insulator layers 154A may be formed by depositing an insulator material over device 100 and etching the insulator material, such that remainders of the insulator material provide insulator layers 154A′ having a first nitrogen concentration. For example, insulator layers 154A′ having a thickness t1 may fill bottoms of source/drain recesses 140A, and insulator layers 154A′ having a thickness t2 may be disposed over source/drain structures 150B. The as-deposited insulator material may be disposed on tops of gate structure 130A and gate structure 130B (e.g., of gate spacers 134 and dummy gate stacks 132 thereof), sidewalls of gate structure 130A and gate structure 130B (e.g., of gate spacers 134 thereof), tops and/or sidewalls of source/drain structures 150B (e.g., of doped semiconductor layers 160B thereof), sidewalls of semiconductor layers 120, sidewalls of inner spacers 145, sidewalls of mesas 105P′, and tops of mesa 105′. In some embodiments, because of properties of a deposition process (e.g., PVD), a thickness of the insulator material over horizontally oriented surfaces (e.g., tops of undoped semiconductor layers 152, top of gate structure 130A, top of gate structure 130B, and tops of source/drain structures 150B) may be greater than a thickness of the insulator material over vertically oriented surfaces (e.g., sidewalls of gate structure 130A, sidewalls of gate structure 130B, sidewalls of semiconductor layers 120, and sidewalls of inner spacers 145). In such embodiments, parameters of the etching may be tuned to remove vertically oriented portions of the insulator material, such as that on sidewalls of gate structure 130A, sidewalls of gate structure 130B, sidewalls of semiconductor layers 120, and sidewalls of inner spacers 145, and because of etch loading effects, the etching may remove horizontally oriented portions of the insulator material on top of gate structure 130A and top of gate structure 130B, but not (or minimally) remove horizontally oriented portions and/or vertically oriented portions of the insulator material in bottoms of source/drain recesses 140A. For example, the etching process may thin portions of the insulator material in bottoms of source/drain recesses 140 but not substantially remove such portions. Further, because of etch loading effects, the etching process may thin the insulator material disposed over source/drain structures 150B more than the insulator material disposed over undoped semiconductor layers 152 of source/drain structures 150A, such that thickness t2 is less than thickness t1 in the depicted embodiment. In some embodiments, thickness t2 is about the same as thickness t1. In some embodiments, the etching process completely removes the insulator material disposed over source/drain structures 150B, and device region 102B is free of insulator layers 154A′/insulator layers 154A. In some embodiments, the as-deposited insulator material fills source/drain recesses 140A and the etching recesses the insulator material at least to bottom sacrificial layers 115 and/or bottom inner spacers 145. In such embodiments, the etching process may partially remove (e.g., thin) or completely remove the insulator material disposed over source/drain structures 150B. The etching may be a dry etch, a wet etch, other suitable etch, or combinations thereof.

The present disclosure recognizes that subsequent processing of device 100 may undesirably reduce thickness t1 of insulator layers 154A′. For example, an etching process implemented to remove a mask and/or a patterning layer from device region 102A, such as that described with reference to FIG. 2G and FIG. 3D, may undesirably etch insulator layers 154A′. In some instances, thickness t1 may be reduced to less than 3 nm. Insulator layers 154A′ having thicknesses less than 3 nm have been observed to negligibly reduce and/or prevent leakage current, if at all, thereby negating the purpose of incorporating insulator layers 154A′ into source/drain structures 150A. This issue is exacerbated when thickness t1 of insulator layers 154A′ is not uniform. For example, thickness t1 of edges/end portions of insulator layers 154A′ may be less than thickness t1 of central portions of insulator layers 154A′, making edges/end portions of insulator layers 154A′ more susceptible to subsequently performed etching processes. In some instances, subsequent etching processes may completely remove the thinner edges of insulator layers 154A′ in device region 102A and undesirably expose and/or damage underlying undoped semiconductor layers 152 and/or mesas 105P′ in device region 102A. Insulator layers 154A′ having thicknesses less than 3 nm may thus lead to, instead of preventing, leakage current. Simply increasing thickness t1 by increasing a thickness of the as-deposited insulator material and/or etching less of the as-deposited insulator material to compensate and/or account for thickness reductions that may occur during subsequent fabrication has been observed to leave residual insulator material along sidewalls of source/drain recesses 140A (e.g., along sidewalls of semiconductor layers 120 and/or sidewalls of inner spacers 145) that inhibits growth and/or deposition of doped semiconductor layers 156A, thereby degrading source/drain strain.

Referring to FIG. 2E and FIG. 3B, the present disclosure thus proposes performing a treatment process 165 on insulator layers 154A′. Treatment process 165 is configured to modify a composition and/or a quality of insulator layers 154A′, thereby resulting in insulators layers 154A. For example, treatment process 165 is configured to provide insulator layers 154A with a thickness t3 that is greater than thickness t1 of insulator layers 154A′, a second nitrogen concentration that is greater than the first nitrogen concentration of insulator layers 154A′, an etch rate (e.g., a wet etch rate) to a given etchant (e.g., a fluorine-based etchant, such as diluted hydrofluoric acid) that is less than an etch rate of insulator layers 154A′ to the given etchant, or combinations thereof. FIG. 4 depicts another embodiment of insulator layer 154A′ (untreated) and insulator layer 154A (treated), where treatment process 165 increases bottom insulator layer thickness. In FIG. 4, undoped semiconductor layers 152, insulator layer 154A′, and insulator layer 154A have convex top surfaces, instead of concave top surfaces, and the present disclosure contemplates source/drain structures 150 having such configurations in some embodiments.

Treatment process 165 includes a nitrogen thermal treatment, such as an annealing process performed in a nitrogen-containing ambient. In the depicted embodiment, the nitrogen-containing ambient is N₂, and the nitrogen thermal treatment is an N₂ anneal. In some embodiments, the annealing process is a rapid thermal anneal (RTA), such as an N₂ RTA. In some embodiments, the annealing process is a spike annealing, such as an N₂ spike anneal (e.g., a spike RTA). In some embodiments, the annealing process is a furnace annealing, such as an N₂ furnace anneal. Parameters of the annealing process (e.g., anneal temperature, anneal time, anneal ambient, pressure, etc.) may be configured to increase a thickness of insulator layers 154A′, increase a nitrogen concentration in insulator layers 154A′, increase silicon-nitrogen bonds in insulator layers 154A′, reduce nitrogen-hydrogen bonds in insulator layers 154A′, or combinations thereof. In some embodiments, an annealing temperature is about 600° C. to about 900° C. In some embodiments, an anneal time is about 1 second to about 5 minutes. In some embodiments, a pressure maintained in a process chamber during the anneal is about 1 torr to about 100 torr. In some embodiments, the nitrogen thermal treatment heats device 100, features thereof (e.g., insulator layers 154A′), an ambient/environment containing device 100, or combinations thereof to a temperature (e.g., the annealing temperature) that increases a thickness of insulator layers 154A′, a nitrogen concentration in insulator layers 154A′, silicon-nitrogen bonding in insulator layers 154A′, or combinations thereof. In some embodiments, the nitrogen thermal treatment drives (diffuses) nitrogen into insulator layers 154A′.

In some embodiments, treatment process 165 further includes a silicon implantation process, which may implant and/or incorporate silicon into insulator layers 154A′. The silicon implantation process may be performed before or after the nitrogen thermal treatment. The silicon implantation process may provide insulator layers 154A with a silicon concentration that is greater than a silicon concentration of insulator layers 154A′ and/or further reduce the etch rate of insulator layers 154A to the given etchant (e.g., a fluorine-based etchant, such as diluted hydrofluoric acid) compared to the etch rate of insulator layers 154A′ to the given etchant. Parameters of the silicon implantation process (e.g., implant energy, implant dose/concentration, implant angle (e.g., tilt angle and/or twist angle), implant temperature, implant time, implant ambient, pressure, etc.) may be configured to increase a silicon concentration and/or increase silicon-nitrogen bonding in insulator layers 154A′. In some embodiments, a silicon implant energy is about 3 kiloelectron volts (keV) to about 19 keV. In some embodiments, a silicon implant dose is about 1×10¹⁹ ions/cm² (cm⁻²) to about 1×10²⁰ cm⁻². In some embodiments, insulator layers 154A are “silicon rich” after the silicon implantation process. In some embodiments, parameters of the nitrogen thermal treatment may be determined based on whether treatment process 165 also includes the silicon implantation process. For example, the nitrogen thermal treatment may be performed for a shorter time at a higher temperature when treatment process 165 includes the silicon implantation process. In some embodiments, the nitrogen thermal treatment may be performed at a temperature of about 800° C. to about 950° C. for about 1.5 seconds to about 2 seconds. In such embodiments, the nitrogen thermal treatment may be an N₂ spike RTA. Further, in such embodiments, the nitrogen thermal treatment may incorporate low concentrations of oxygen, and the annealing process may be performed in a nitrogen-and-oxygen containing ambient. For example, a concentration of oxygen (e.g., O₂) in the nitrogen-and-oxygen containing ambient may be less than about 500 parts per million (ppm).

Treatment process 165 provides insulator layers 154A with a thickness (e.g., thickness t3) that is at least 3 nm. In some embodiments, thickness t3 is about 3 nm to about 8 nm. For example, thickness t3 is about 3.5 nm to about 4.5 nm. Bottom insulator layers having thicknesses of at least 3 nm can withstand subsequent processing, such that even if the bottom insulator layers are etched and/or thinned during subsequent processing, a sufficient amount of the bottom insulator layers remains between doped semiconductor layers 156A and underlying undoped semiconductor layers 152/mesas 105P′, and source/drain structures 150A are provided with bottom source/drain isolation that adequately inhibits and/or prevents leakage current. Reducing source/drain-mesa leakage current improves performance of device 100, for example, by improving transistor gain in device region 102A. In some embodiments, treatment process 165 increases insulator layer thickness by about 0.4 nm to about 1.4 nm (i.e., thickness t1 is increased by about 0.4 nm to about 1.4 nm), such that thickness t3 is at least 3 nm. In some embodiments, the nitrogen thermal treatment plus silicon implantation process increases insulator thickness (e.g., by about 0.7 nm to about 1.4 nm) more than the nitrogen thermal treatment alone (e.g., by about 0.4 nm to about 0.6 nm). In some embodiments, thickness t3 of edges/end portions of insulator layers 154A is less than thickness t3 of central portions of insulator layers 154A, and at least thickness t3 of central portions of insulator layers 154A is greater than 3 nm. In some embodiments, both thickness t3 of edges/end portions of insulator layers 154A and thickness t3 of central portions of insulator layers 154A are greater than 3 nm. Treatment process 165 may also provide insulator layers 154A with a more uniform thickness compared to insulator layers 154A′. For example, a difference in thickness t3 of edges/end portions of insulator layers 154A and thickness t3 of central portions of insulator layers 154A may be less than a difference in thickness t1 of edges/end portions of insulator layers 154A′ and thickness t1 of central portions of insulator layers 154A′. Treatment process 165 may thus improve bottom source/drain insulation by also improving uniformity of bottom insulator layers (e.g., by reducing center-to-edge thickness differences thereof) (see, e.g., FIG. 4). In some embodiments, treatment process 165 increases a thickness of edges/end portions of the bottom source/drain insulation more than a thickness of central portions of the bottom source/drain insulation. For example, a difference between thickness t1 of edge/end portions of insulator layers 154A′ and thickness t3 of edge/end portions of insulator layers 154A may be greater than a difference between thickness t1 of central portions of insulator layers 154A′ and thickness t3 of central portions of insulator layers 154A. See, e.g., FIG. 4.

Treatment process 165 may also create, repair, and/or enhance silicon-nitrogen bonding (e.g., Si—N bonds) and reduce nitrogen-hydrogen bonding (e.g., N(—H)ₓ bonds) in insulator layers 154A′, such that insulator layers 154A may have greater Si—N bonds and less N—H bonds (e.g., N(—H)ₓ bonds) than insulator layers 154A′. Increasing silicon-nitrogen bonding and reducing nitrogen-hydrogen bonding may increase insulator thickness and/or decrease an etch rate of insulator layers 154A to a given etchant compared to an etch rate of insulator layers 154A′ to the given etchant, such as described further below. In some embodiments, performing treatment process 165 on insulator layers 154A′ may provide insulator layers 154A with a wet etch rate to a given etchant (e.g., a fluorine-based etchant, such as diluted hydrofluoric acid) that is about 35% to about 75% less than a wet etch rate of insulator layers 154A′ to the given etchant. For example, an amount of insulator layers 154A (e.g., angstroms (Å) thereof) removed per minute by the etchant is less than an amount of insulator layers 154A′ removed per minute by the etchant. Bottom source/drain insulation is thus provided with greater etch resistance to subsequent processing (i.e., the lower etch rate means less removal of the bottom source/drain insulation during subsequent processing), thereby improving bottom source/drain insulation.

Referring to FIG. 2F and FIG. 3C, fabrication of device 100 may include forming a mask 168 over device region 102A and device region 102B. A composition of mask 168 is different than compositions of source/drain structures 150A (e.g., insulator layers 154A thereof), source/drain structures 150B (e.g., doped semiconductor layers 160B thereof), semiconductor layers 120, gate structure 130A, gate structure 130B, inner spacers 145, or combinations thereof to enable selective removal/etching therebetween. In some embodiments, mask 168 includes metal and oxygen and/or nitrogen (i.e., mask 168 is a metal oxide mask and/or a metal nitride mask). For example, mask 168 may include aluminum and oxygen and/or nitrogen, and mask 168 may be an aluminum oxide mask, an aluminum oxynitride mask, or an aluminum nitride mask. In the depicted embodiment, mask 168 is an aluminum oxide mask (e.g., an Al₂O₃ mask). Mask 168 may be a passivation layer over source/drain structures 150B. The passivation layer may protect source/drain structures 150B while forming additional layers of source/drain structures 150A. For example, the passivation layer may prevent semiconductor material (e.g., epitaxial material) from depositing and/or growing on doped semiconductor layers 156B, prevent unintentional doping of source/drain structures 150B (e.g., with n-type dopant), prevent other modifications to and/or defects in source/drain structures 150B, or combinations thereof while doped semiconductor layers 156A are formed in source/drain recesses 140A.

The present disclosure recognizes that a composition and/or a quality of mask 168, as deposited, may be insufficient to withstand processing associated with forming additional layers of source/drain structures 150A. For example, mask 168 may be damaged and/or undesirably removed/thinned during a pre-clean process, such as an etching process, performed on source/drain recesses 140A before forming doped semiconductor layers 156A therein. In embodiments where the pre-clean process is a wet etch, an etch solution (e.g., including ammonia (NH₃) and/or hydrogen fluoride (HF)) may undesirably react with mask 168, resulting in unintentional etching of mask 168. Such undesirable reaction is particularly prevalent when mask 168 is an aluminum oxide mask because the etchant (e.g., NH₃ and/or HF thereof) may react with mask 168 (e.g., Al(OH)₃ bonds that may be present at a surface thereof) and form (NH₄)₃AlF₆ and outgassing. In some instances, the etchant may completely remove portions of mask 168 and expose underlying source/drain structures 150B, which may lead to unintentional etching and/or loss of source/drain structures 150B (e.g., doped semiconductor layers 160B) and/or undesired deposition/growth of semiconductor materials intended for device region 102A on source/drain structures 150B. Simply increasing a thickness of as-deposited mask 168 to compensate and/or account for thickness reductions, and thus unintended exposure of source/drain structures 150B, that may occur during the pre-clean process and/or other processes associated with forming doped semiconductor layers 156A has been observed to leave residual mask material (e.g., aluminum oxide) in source/drain recesses 140A that inhibits growth and/or deposition of doped semiconductor layers 156A, thereby degrading source/drain strain.

The present disclosure thus proposes performing a treatment process 170 on mask 168. Treatment process 170 is configured to modify a composition and/or a quality of mask 168, such that mask 168 may better withstand the source/drain pre-clean process and/or other subsequent processing. For example, treatment process 170 is configured to increase a density, reduce a hydrogen concentration (e.g., at a surface thereof), improve hydrogen bonding, reduce an etch rate (e.g., a wet etch rate) to a given etchant (e.g., NH₃ and/or HF), or combinations thereof. Increasing a density of mask 168, reducing hydrogen content of mask 168, and/or improving hydrogen bonding may decrease an etch rate of mask 168 to a given etchant compared to an etch rate of mask 168 without treatment. In some embodiments, performing treatment process 170 on mask 168 reduces its hydrogen concentration (H %) by greater than about 20%. In some embodiments, performing treatment process 170 on mask 168 increases its density by greater than about 2%. In some embodiments, performing treatment process 170 on mask 168 reduces its wet etch rate to a given etchant (e.g., NH₃ and/or HF) by greater than about 10%. For example, an amount of treated mask 168 (e.g., Å) removed per minute by the etchant is less than an amount of untreated mask 168 removed per minute by the etchant. Mask 168 is thus provided with greater etch resistance to the source/drain pre-clean process and/or other processing associated with forming the additional layers of source/drain structures 150A, thereby reducing and/or preventing loss of mask 168 and damage to source/drain structures 150B.

Treatment process 170 includes a nitrogen thermal treatment, such as an annealing process performed in a nitrogen-containing ambient. In the depicted embodiment, the nitrogen-containing ambient is N₂, and the nitrogen thermal treatment is an N₂ anneal. In some embodiments, the annealing process is an RTA, such as an N₂ RTA. In some embodiments, the annealing process is a spike annealing, such as an N₂ spike anneal (e.g., a spike RTA). In some embodiments, the annealing process is a furnace annealing, such as an N₂ furnace anneal. Parameters of the annealing process (e.g., anneal temperature, anneal time, anneal ambient, pressure, etc.) may be configured to increase a density of mask 168, reduce a hydrogen concentration of mask 168 (e.g., at a surface thereof), improve hydrogen bonding in mask 168 (e.g., improve bond strength of hydrogen in and/or at a surface of mask 168, which may slow reaction of the etchant (e.g., NH₃ and/or HF) with hydrogen constituents (e.g., Al(OH)₃ bonds) of mask 168, and thus slow removal of hydrogen and portions of mask 168), or combinations thereof. In some embodiments, the nitrogen thermal treatment heats device 100, features thereof (e.g., mask 168), an ambient/environment containing device 100, or combinations thereof to a desired temperature (e.g., the anneal temperature). In some embodiments, the nitrogen thermal treatment drives (diffuses) nitrogen into mask 168. In some embodiments, an annealing temperature is about 600° C. to about 900° C. Though such high annealing temperatures (e.g., above about 700° C.) may decrease a thickness of mask 168, density increases provided by such high annealing temperatures sufficiently improve a composition of mask 168, such that it is more resistant to the pre-clean process and/or other subsequent processes. In some embodiments, an anneal time is about 1 second to about 5 minutes. In some embodiments, a pressure maintained in a process chamber during the nitrogen thermal treatment is about 1 torr to about 100 torr.

Referring to FIG. 2G and FIG. 3D, mask 168 is removed from device region 102A by a patterning process, thereby exposing source/drain recesses 140A (e.g., insulator layers 154A thereof). For example, mask 168 has an opening 169 therein that overlaps device region 102A, such that mask 168 covers device region 102B (e.g., a p-type transistor region), but not device region 102A (e.g., an n-type transistor region). The patterning process may include performing a lithography process to form a patterned resist layer that covers mask 168 over device region 102B and exposes mask 168 over device region 102A (e.g., the patterned resist layer has an opening therein that overlaps device region 102A) and performing an etching process to selectively remove exposed mask 168. In the depicted embodiment, the etching process is configured to selectively remove mask 168 (e.g., a nitrogen-treated aluminum oxide material) with negligible (to no) etching of source/drain structures 150A (e.g., insulator layers 154A thereof (e.g., a nitrogen-treated silicon nitride material)), gate structure 130A, substrate isolation structures 125, or combinations thereof. The etching process is a dry etch, a wet etch, other suitable etch, or combinations thereof. For example, the etching process may be a wet etch that implements a hydrofluoric acid (HF) solution or a diluted HF (DHF) solution. As described above, because insulator layers 154A (e.g., nitrogen-treated silicon nitride material) have been made thicker by treatment process 165 and/or N—H bonds (e.g., N(—H)ₓ bonds) have been reduced in insulator layers 154A by treatment process 165, insulator layers 154A have a greater etch resistance to the wet etch, such that insulator layers 154A may not be (or negligibly) etched by the wet etchant (e.g., DHF solution). For example, an HF-based etchant may react with Si—N bonds and/or N—H bonds (e.g., N(—H)ₓ bonds) of insulator layers 154A to break Si—N bonds thereof and substitute Si—NH₂ bonds with Si—F bonds, thereby slightly etching and/or modifying insulator layers 154A. However, since insulator layers 154A have less N—H bonds (e.g., N(—H)ₓ bonds) than insulator layers 154A′, it is more difficult for the HF-based etchant to react with insulator layers 154A, break Si—N bonds, and substitute Si—NH₂ bonds with Si—F bonds. Further, because insulator layers 154A are at least 3 nm thick, insulator layers 154A may tolerate some etching thereof, yet still remain thick enough to provide adequate bottom source/drain insulation. Accordingly, because the disclosed source/drain fabrication process implements treatment process 165, any removal of insulator layers 154A may be negligible, and insulator layers 154A may still provide bottom source/drain insulation that reduces/prevents leakage current.

Referring to FIG. 2G and FIG. 3E, doped semiconductor layers 156B may be formed in source/drain recesses 140B over insulator layers 154B and/or undoped semiconductor layers 152 while device region 102B is covered by mask 168 (e.g., a nitrogen-doped aluminum oxide mask). Doped semiconductor layers 156A fill remainders of source/drain recesses 140A, and doped semiconductor layers 156A are coupled to edges/end portions of semiconductor layers 120 in device region 102A. In the depicted embodiment, doped semiconductor layers 156A include doped semiconductor layers 158A and doped semiconductor layers 160A. Doped semiconductor layers 158A may be formed over semiconductor layers 120 (e.g., sidewalls and/or ends thereof) and partially fill source/drain recesses 140A, and doped semiconductor layers 160A may be formed over doped semiconductor layers 158A and/or insulator layers 154A and fill remainders of source/drain recesses 140A. Doped semiconductor layers 160A are separated from semiconductor layers 120 by doped semiconductor layers 158A, and doped semiconductor layers 160A are separated from undoped epitaxial layers 152 by insulator layers 154A. In the depicted embodiment, doped semiconductor layers 158A are discontinuous and formed of discrete, separate portions, each of which is disposed on an end of a respective semiconductor layer 120 (i.e., portions of doped semiconductor layers 158A disposed on adjacent semiconductor layers 120 are not connected to one another). In such embodiment, doped semiconductor layers 160A may wrap doped semiconductor layers 158A, and doped semiconductor layers 160A may extend to inner spacers 145. In some embodiments, one or more of the discrete, separate portions of doped semiconductor layers 158A may wrap a respective semiconductor layer 120, such that the discrete, separate portions are formed over a top and/or a bottom of the respective semiconductor layer 120. In some embodiments, the discrete, separate portions extend over and/or to inner spacers 145. In some embodiments, one or more of the discrete, separate portions of doped semiconductor layers 158A are connected, such that doped semiconductor layers 158A may form sidewalls of source/drain structures 150A above mesas 105P′ and/or doped semiconductor layers 160A may be separated from inner spacers 145 by doped semiconductor layers 158A.

Doped semiconductor layers 158A and doped semiconductor layers 160A include silicon, germanium, silicon germanium, other suitable semiconductor materials, or combinations thereof. In some embodiments, doped semiconductor layers 158A and doped semiconductor layers 160A include the same semiconductor material with different constituent concentrations. For example, doped semiconductor layers 158A and doped semiconductor layers 160A may include silicon and n-type dopant (e.g., phosphorous and/or arsenic), but different n-type dopant concentrations. In some embodiments, doped semiconductor layers 158A have a smaller n-type dopant concentration (e.g., P %) than doped semiconductor layers 160A, which may reduce crystalline dislocation, reduce other crystalline defects, maximize strain (and thereby enhance carrier mobility, which increases drive current), or combinations thereof. In some embodiments, doped semiconductor layers 158A have an n-type dopant concentration (e.g., a phosphorous concentration) of about 1×10²⁰ cm⁻³ to about 5×10²⁰ cm⁻³, and doped semiconductor layers 160A have an n-type dopant concentration (e.g., a phosphorous concentration) of about 5×10²⁰ cm⁻³ to about 2×10²¹ cm⁻³. In such embodiments, doped semiconductor layers 160A may be referred to as heavily doped semiconductor layers, and doped semiconductor layers 158A may be referred to as lightly doped semiconductor layer. In some embodiments, doped semiconductor layers 158A and doped semiconductor layers 160A have different semiconductor materials, which may have the same or different constituent concentrations. In some embodiments, doped semiconductor layers 156A include materials and/or dopants that provide desired tensile stress in channel regions of device region 102A (e.g., semiconductor layers 120).

Doped semiconductor layers 158A may be deposited on and/or grown from semiconductor layers 120, and doped semiconductor layers 160A may be deposited on and/or grown from doped semiconductor layers 158A. In some embodiments, doped semiconductor layers 158A and doped semiconductor layers 160A are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of semiconductor layers 120, doped semiconductor layers 158A, or combinations thereof. Epitaxial growth/deposition conditions, such as those described herein, are tuned to selectively deposit (grow) semiconductor material (e.g., silicon) on semiconductor surfaces (e.g., semiconductor layers 120 and/or doped semiconductor layers 158A) while limiting (or preventing) growth of semiconductor material from dielectric surfaces and/or non-semiconductor surfaces (e.g., inner spacers 145, dummy gate stacks 132, gate spacers 134, and/or substrate isolation structures 125). In some embodiments, doped semiconductor layers 158A and/or doped semiconductor layers 160A are doped during deposition (i.e., in-situ doping), such as by adding dopants to a source material of the SEG processes. In some embodiments, doped semiconductor layers 158A and/or doped semiconductor layers 160A are doped after deposition, such as by an ion implantation process. In some embodiments, annealing is performed to activate dopants in doped semiconductor layers 158A, doped semiconductor layers 160A, other source/drain regions, such as source/drain junction implant regions, or combinations thereof.

In some embodiments, a pre-clean process, such as an etching process, is performed on source/drain recess 140A before forming doped semiconductor layers 156A therein. For example, the etching process may be a wet etch that implements an NH₃ solution and/or an HF solution. As described above, because mask 168 (e.g., nitrogen-treated aluminum oxide material) has been made denser by treatment process 170, hydrogen content (H %) has been reduced in mask 168 by treatment process 170, and/or hydrogen bonding has been improved in mask 168 (e.g., bond strength of hydrogen in and/or at a surface of mask 168 is greater) by treatment process 170, mask 168 has a greater etch resistance to the wet etch, such that mask 168 may not be (or negligibly) etched by the wet etchant (e.g., NH₃+HF solution). For example, an NH₃-based and/or an HF-based etchant may react with hydrogen constituents (e.g., Al(OH)₃ bonds) of mask 168, thereby slightly etching and/or modifying mask 168. However, since treated mask 168 is denser, has less hydrogen content, and has stronger hydrogen bonding, such reactions may occur less and/or more slowly, thereby reducing any etching/removal of mask 168. Accordingly, because the disclosed source/drain fabrication process implements treatment process 170, any removal of mask 168 may be negligible, and mask 168 may still provide sufficient passivation and protection of source/drain structures 150B, thereby preventing or reducing any loss of source/drain structures 150B while forming source/drain structures 150A.

Referring to FIG. 2H and FIG. 3F, mask 168 may be removed after forming the additional layers of source/drain structures 150A by any suitable process, such as an etching process. In the depicted embodiment, the etching process is configured to selectively remove mask 168 (e.g., a nitrogen-doped aluminum oxide material) with negligible (to no) etching of source/drain structures 150A, source/drain structures 150B, gate structure 130A, gate structure 130B, substrate isolation structures 125, or combinations thereof. The etching process is a dry etch, a wet etch, other suitable etch, or combinations thereof, and the etching process may implement a same etchant as or a different etchant than the etching process used for patterning mask 168 (i.e., when a portion thereof is removed to expose device region 102A in FIG. 2G and FIG. 3D). In the depicted embodiment, the etching process implements a different etchant to remove mask 168 from device region 102B. For example, the etching process may be a wet etch that implements a sulfuric peroxide mix (SPM) solution (i.e., mixture of H₂SO₄ and H₂O₂).

Referring to FIG. 2I, fabrication of device 100 may include forming a dielectric layer 175 over source/drain structures 150 and substrate isolation structures 125. Dielectric layer 175 may fill spaces between adjacent gate structures, such as spaces between gate spacers 134 of gate structure 130A and gate spacers 134 of gate structure 130B, and spaces between adjacent source/drain structures 150. Forming dielectric layer 175 may include depositing a contact etch stop layer (CESL), depositing an interlayer dielectric (ILD) layer over the CESL, and performing a CMP and/or other planarization process until reaching dummy gate stacks 132. The planarization process may partially remove dummy gate stacks 132, such as hard masks 138 thereof, to expose underlying dummy (e.g., poly) gates 136. The planarization process may reduce heights of dummy gate stacks 132 and/or gate spacers 134.

The ILD layer includes a dielectric material including, for example, silicon oxide, carbon doped silicon oxide, silicon nitride, silicon oxynitride, tetraethylorthosilicate (TEOS)-formed oxide, BSG, PSG, borophosphosilicate glass, fluorosilicate glass, xerogel, aerogel, amorphous fluorinated carbon, parylene, benzocyclobutene-based (BCB) dielectric material, polyimide, other suitable dielectric material, or combinations thereof. In some embodiments, the ILD layer includes a low-k dielectric material having a dielectric constant that is less than a dielectric constant of silicon dioxide (e.g., k<3.9). In some embodiments, the ILD layer includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. The CESL includes a material different than the ILD layer, such as a dielectric material that is different than the dielectric material of the ILD layer. For example, where the ILD layer includes a silicon- and -oxygen comprising low-k dielectric material, the CESL may include silicon and nitrogen, such as silicon nitride or silicon oxynitride. The ILD layer and/or the CESL may have a multilayer structure and/or include multiple dielectric materials.

A gate replacement process may then be performed to replace dummy gates 136 with a gate stack 180A and a gate stack 180B. For example, dummy gates 136 are removed to form gate openings (formed between gate spacers 134 and/or inner spacers 145) that expose channel regions of multilayer stacks 110 (e.g., semiconductor layers 120 and sacrificial layers 115). In some embodiments, an etching process may selectively remove dummy gates 136 with respect to dielectric layer 175, gate spacers 134, inner spacers 145, sacrificial layers 115, semiconductor layers 120, or combinations thereof. In other words, the etching process removes dummy gates 136 with negligible (to no) removal of dielectric layer 175, gate spacers 134, inner spacers 145, sacrificial layers 115, semiconductor layers 120, or combinations thereof. The etching process is a dry etch, a wet etch, other suitable etch process, or combinations thereof. In some embodiments, the etching process uses a patterned mask layer as an etch mask, where the patterned mask layer covers dielectric layer 175 and/or gate spacers 134.

During the gate replacement process, before forming gate stack 180A and gate stack 180B in the gate openings, a channel release process may be performed to form suspended channel layers. For example, sacrificial layers 115 exposed by the gate openings may be selectively removed to form air gaps between semiconductor layers 120 and between semiconductor layers 120 and mesas 105P′, thereby suspending semiconductor layers 120 in channel regions. In the depicted embodiment, each channel region has three suspended semiconductor layers 120, which are referred to hereafter as channel layers 120′, vertically stacked along the z-direction for providing three channels through which current can flow between respective source/drain structures 150 during operation of transistors of device 100. In some embodiments, an etching process selectively etches sacrificial layers 115 with minimal (to no) etching of semiconductor layers 120, mesas 105P′, gate spacers 134, inner spacers 145, dielectric layer 175, or combinations thereof. In some embodiments, an etchant is selected for the etch process that etches silicon germanium (i.e., sacrificial layers 115) at a higher rate than silicon (i.e., semiconductor layers 120 and mesas 105P′) and dielectric materials (i.e., gate spacers 134, inner spacers 145, and/or dielectric layer 175) (i.e., the etchant has a high etch selectivity with respect to silicon germanium). The etching process is a dry etch, a wet etch, other suitable etch process, or combinations thereof. In some embodiments, before performing the etching process, an oxidation process may be implemented to convert sacrificial layers 115 into silicon germanium oxide features, where the etching process then removes the silicon germanium oxide features. In some embodiments, during and/or after removing sacrificial layers 115, an etching process may be performed to modify a profile of semiconductor layers 120 to achieve target dimensions and/or target shapes for channel layers 120′.

Gate stack 180A of gate structure 130A and gate stack 180B of gate structure 130B may then be formed in the gate openings. Gate stack 180A and gate stack 180B (also referred to as high-k/metal gates) are disposed between respective gate spacers 134, between respective inner spacers 145, between respective channel layers 120′, and between respective channel layers 120′ and respective mesas 105P′. In the depicted embodiment, where device 100 includes GAA transistors, gate stack 180A and gate stack 180B may surround respective channel layers 120′, for example, in the Y-Z plane. In some embodiments, gate stack 180A and gate stack 180B may wrap and/or partially surround respective channel layers 120′ (i.e., be disposed on at least two sides thereof), such as where device 100 includes fork-sheet transistors.

Gate stack 180A includes a gate dielectric 182A, and gate stack 180B includes a gate dielectric 182B. Gate dielectric 182A and gate dielectric 182B are disposed on respective channel layers 120′, respective inner spacers 145, respective gate spacers 134, substrate isolation structures 125, or combinations thereof. Compositions and/or configurations of gate dielectric 172A and gate dielectric 172B may be the same or different. For example, a composition and/or configuration of gate dielectric 182A may be different than a composition and/or a configuration of gate dielectric 182B, such as where device region 102A and device region 102B are configured for different type transistors. Gate dielectric 182A and gate dielectric 182B each include at least one dielectric layer, such as an interfacial layer and/or a high-k dielectric layer. The interfacial layer includes a dielectric material, such as SiO₂, SiGeOx, HfSiO, SiON, other dielectric material, or combinations thereof. The high-k dielectric layer includes a high-k dielectric material, which generally refers to dielectric materials having a dielectric constant greater than a dielectric constant of silicon dioxide, such as HfO₂, HfSiO, HfSiO₄, HfSION, HfLaO, HfTaO, HfTIO, HfZrO, HfAlOx, ZrO, ZrO₂, ZrSiO₂, AlO, AlSiO, Al₂O₃, TIO, TiO₂, LaO, LaSiO, LaO₃, La₂O₃, Ta₂O₃, Ta₂O₅, Y₂O₃, SrTiO₃, BaZrO, BaTiO₃ (BTO), (Ba,Sr) TiO₃ (BST), HfO₂—Al₂O₃, other high-k dielectric material, or combinations thereof. In some embodiments, gate dielectric 182A and gate dielectric 182B each include a hafnium-based oxide (e.g., HfO₂) layer and/or a zirconium-based oxide (e.g., ZrO₂) layer.

Further, gate stack 180A includes a gate electrode 184A disposed over gate dielectric 182A, and gate stack 180B includes a gate electrode 184B disposed over gate dielectric 182B. Compositions and/or configurations of gate electrode 184A and gate electrode 184B may be the same or different. For example, a composition and/or configuration of gate electrode 184A may be different than a composition and/or a configuration of gate electrode 184B, such as where device region 102A and device region 102B are configured for different type transistors. In some embodiments, gate electrode 184A and gate electrode 184B each include an electrically conductive layer formed of an electrically conductive material, such as Al, Cu, Ti, Ta, W, Mo, Co, TaN, NiSi, CoSi, TiN, WN, TiAl, TiAIN, TaCN, TaC, TaSiN, other electrically conductive material, or combinations thereof. In some embodiments, the electrically conductive layer includes a work function layer, which may be tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAIC, TIAISIC, TaC, TaCN, TaSiN, TiSiN, TiN, TaN, TaSN, WN, WCN, ZrSi₂, MoSi₂, TaSi₂, NiSi₂, TaAl, TaAIC, TaSiAIC, TiAIN, or combinations thereof. In some embodiments, the electrically conductive layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Gate stack 180A and gate stack 180B are configured to achieve desired functionality according to design requirements of device 100, and gate stack 180A and gate stack 180B may have different layers in different device regions depending on configurations thereof. For example, a number, configuration, materials, or combinations thereof of layers of gate dielectric 182A and/or gate electrode 184A corresponding with device region 102A (e.g., an n-type transistor region) may be different than a number, configuration, materials, or combinations thereof of layers of gate dielectric 182B and/or gate electrode 184B corresponding with device region 102B (e.g., a p-type transistor region). Forming gate stack 180A and gate stack 180B may include depositing gate dielectric material (e.g., interfacial layers, high-k dielectric layers, etc.) that partially fill the gate openings, depositing gate electrode material (e.g., work function layers, barrier layers, bulk layers, etc.) that fill remainders of the gate openings, and performing a planarization process to remove portions of the gate dielectric material and/or portions of the gate electrode material over dielectric layer 175. Gate stack 180A of gate structure 130A and gate stack 180B may be formed simultaneously, partially simultaneously, or separately. For example, gate dielectrics 182A and gate dielectric 182B (or sublayers thereof) may be formed simultaneously. In another example, bulk layers of gate electrode 184A and gate electrode 184B may be formed simultaneously, while work function layers (or sublayers thereof) of gate electrode 184A and gate electrode 184B may be formed separately. Though the depicted embodiment fabricates gate stack 180A and gate stack 180B according to a gate last process, the present disclosure contemplates embodiments where the metal gate stacks of device 100 may be fabricated according to a gate first process or a hybrid gate last/gate first process.

Fabrication of device 100 may further include etching back gate stack 180A and gate stack 180B and forming hard masks (e.g., self-aligned cap structures) over the etched-back gate stacks 180A, 180B. The hard masks include a material that is different than dielectric layer 175 and/or subsequently formed dielectric layers to achieve etch selectivity. In some embodiments, the hard masks include silicon and nitrogen and/or carbon, such as silicon nitride, silicon oxynitride, silicon carbide, silicon oxycarbide, silicon carbonitride, silicon oxycarbonitride, or combinations thereof. In some embodiments, the hard masks include metal and oxygen and/or nitrogen, such as aluminum oxide, aluminum nitride, aluminum oxynitride, zirconium oxide, zirconium nitride, hafnium oxide, zirconium aluminum oxide, or combinations thereof.

Device 100 may thus include various transistors, such as an n-type transistor in device region 102A and a p-type transistor in device region 102B. The n-type transistor may include respective channels (e.g., channel layers 120′), source/drains (e.g., source/drain structures 150A), and a respective gate (e.g., gate stack 180A). Gate stack 180A is disposed between respective source/drains (e.g., source/drain structures 150A) along the x-direction, and inner spacers 145 are disposed between gate stack 180A and its respective source/drains. Further, gate stack 180A engages respective channels (e.g., channel layers 120′), and the respective channels extend between the respective source/drains (e.g., source/drain structures 150A) along the x-direction. Gate stack 180A may surround its respective channel layers, and along the gate lengthwise direction, each gate may include a gate dielectric (e.g., gate dielectric 182A) and a gate electrode (e.g., gate electrode 184A) that surrounds its respective channels. Further, in the depicted embodiment, the n-type transistor includes bottom source/drain insulation (e.g., insulator layers 154A and undoped semiconductor layers 152), which separates and/or isolates source/drain structures 150A from an underlying substrate (e.g., substrate 105, mesa 105′, mesas 105P′, or combinations thereof), which may reduce and/or eliminate leakage current into the underlying substrate, such as that which may flow from the source/drains into the underlying substrate. Reducing and/or eliminating the unwanted leakage current improves overall transistor performance. As described herein, because the source/drain fabrication process described herein implements treatment process 165, the n-type transistor is provided with improved bottom source/drain insulation, thereby improving leakage current suppression.

The p-type transistor may include respective channels (e.g., channel layers 120′), source/drains (e.g., source/drain structures 150B), and a respective gate (e.g., gate stack 180B). Gate stack 180B is disposed between respective source/drains (e.g., source/drain structures 150B) along the x-direction, and inner spacers 145 are disposed between gate stack 180B and its respective source/drains. Further, gate stack 180B engages respective channels (e.g., channel layers 120′), and the respective channels extend between the respective source/drains (e.g., source/drain structures 150B) along the x-direction. Gate stack 180B may surround its respective channel layers, and along the gate lengthwise direction, each gate may include a gate dielectric (e.g., gate dielectric 182B) and a gate electrode (e.g., gate electrode 184B) that surrounds its respective channels. Further, in the depicted embodiment, the p-type transistor includes bottom source/drain insulation (e.g., insulator layers 154B and undoped semiconductor layers 152), which separates and/or isolates source/drain structures 150B from an underlying substrate (e.g., substrate 105, mesa 105′, mesas 105P′, or combinations thereof), which may reduce and/or eliminate leakage current into the underlying substrate, such as that which may flow from the source/drains into the underlying substrate. Reducing and/or eliminating the unwanted leakage current improves overall transistor performance.

As a result of the source/drain fabrication process described herein, a composition and/or a configuration of the bottom source/drain insulation of the n-type transistor may be different than a composition and/or a configuration of the bottom source/drain insulation of the p-type transistor. For example, a composition and/or a configuration of insulator layers 154A may be different than a composition and/or a configuration of insulator layers 154B. In some embodiments, a nitrogen concentration of insulator layers 154A is greater than a nitrogen concentration of insulator layers 154B. In some embodiments, a silicon concentration of insulator layers 154A is greater than a silicon concentration of insulator layers 154B. In some embodiments, a thickness of insulator layers 154A is greater than a thickness of insulator layers 154B, such as where insulator layers 154A undergo treatment process 165, but insulator layers 154B do not undergo treatment process 165. In some embodiments, insulator layers 154A and insulator layers 154B are formed of the same material (e.g., silicon nitride). In some embodiments, insulator layers 154A and insulator layers 154B are formed of different materials. Further, as a result of the source/drain fabrication process described herein, source/drain structures 150B may have insulator layers 154A disposed over doped semiconductor layers 156B (e.g., doped semiconductor layers 160B thereof), and doped semiconductor layers 160B may be disposed between nitride layers having different nitrogen concentrations, such as insulator layers 154A having a greater nitrogen concentration than insulator layers 154B. In such embodiments, a thickness of insulator layers 154A of source/drain structures 150A may be greater than a thickness of insulator layers 154A of source/drain structures 150B. Further, in such embodiments, residual portions of insulator layers 154A may remain between dielectric layer 175 and doped semiconductor layers 160B after source/drain contact formation. In some embodiments, device region 102B is masked when forming insulator layers 154A and/or insulator material formed over source/drain structures 150B is removed, such that the p-type transistor does not include insulator layers 154A over doped semiconductor layers 156B.

In some embodiments, fabrication of device 100 may be includes replacing sacrificial layers 115 with different sacrificial layers after forming source/drain recesses 140 and before forming inner spacers 145. In such embodiments, after forming source/drain recesses 140, fabrication of device 100 may include performing an etching process that selectively removes sacrificial layers 115 exposed by source/drain recesses 140, thereby forming gaps in channel regions, and semiconductor layers 120 remaining in channel regions provide channel layers 120′ suspended over mesas 105P′ after removing sacrificial layers 115. The etching process may selectively removes sacrificial layers 115 with respect to substrate 105, semiconductor layers 120, gate structure 130A, gate structure 130B, or combinations thereof. In some embodiments, an etchant is selected for the etching process that etches silicon germanium (e.g., sacrificial layers 115) at a higher rate than silicon (e.g., semiconductor layers 120 and mesa 105′) and dielectric materials (e.g., gate spacers 134 and hard masks 138). The etching process is a dry etch, a wet etch, other suitable etch, or combinations thereof. In some embodiments, before the etching process, an oxidation process may be performed to convert sacrificial layers 115 into semiconductor oxide layers (e.g., silicon germanium oxide layers). In such embodiments, the etching process removes semiconductor oxide layers to form the gaps.

In such embodiments, fabrication of device 100 may then include forming second sacrificial layers in the gaps before forming inner spacers 145. A composition of the second sacrificial layers is different than a composition of channel layers 120′ to achieve etch selectivity. For example, the second sacrificial layers and channel layers 120′ include different materials, constituent atomic percentages, constituent weight percentages, other characteristics, or combinations thereof. In some embodiments, the second sacrificial layers may include a dielectric material. The dielectric material may include silicon, oxygen, carbon, nitrogen, other suitable dielectric constituent, or combinations thereof. For example, the dielectric material includes oxygen, and the second sacrificial layers are oxide layers (which may be referred to as dummy oxide interposers (DOIs). In some embodiments, the DOIs are silicon oxide layers.

In some embodiments, the second sacrificial layers are formed by depositing a dielectric layer over device 100 and etching the dielectric layer, such that the dielectric layer is removed from source/drain regions, but not channel regions, of device 100. In some embodiments, the as-deposited dielectric layer may fill the gaps. In some embodiments, the dielectric layer is formed by a conformal deposition process, and the dielectric layer has a conformal thickness. In some embodiments, the etching may remove exposed portions of the dielectric layer (e.g., those not filling the gaps), such as the portions of the dielectric layer disposed on sidewalls of channel layers 120′, sidewalls of mesas 105P′, surfaces of mesa 105′ that form bottoms of source/drain recesses 140, sidewalls and tops of gate spacers 134, and tops of dummy gate stacks 132 (e.g., hard masks 138 thereof). The dielectric material may be removed by a dry etch, a wet etch, other suitable etch, or combinations thereof. In some embodiments, the second sacrificial layers (e.g., dielectric layers) are formed by an oxidation process, such as thermal oxidation process. In some embodiments, the second sacrificial layers are formed by atomic layer deposition (ALD), plasma enhanced chemical vapor deposition (PECVD), other suitable deposition process, or combinations thereof.

In such embodiments, in FIG. 2B, the first etching process implemented when forming inner spacers 145 may selectively etch the second sacrificial layers with negligible (to no) etching of semiconductor layers 120, mesas 105P′, dummy gate stacks 132 (e.g., hard masks 138 thereof), gate spacers 134, substrate isolation structures 125, or combinations thereof. Further, in such embodiment, in FIG. 2I, fabrication of device 100 may include removing the second sacrificial layers, instead of sacrificial layers 115, thereby forming gaps (openings) that expose channel layers 120′. Gate openings are thus extended between channel layers 120′ and between channel layers 120′ and mesas 105P′. In such embodiments, the etching process removes the second sacrificial layers with negligible (to no) removal of channel layers 120′, inner spacers 145, gate spacers 134, dielectric layer 175, or combinations thereof. For example, an etchant is selected for the etching process that etches a dielectric material having a first composition (e.g., the second sacrificial layers) at a higher rate than silicon (e.g., channel layers 120′) and dielectric materials having compositions different than the first composition (e.g., inner spacers 145, gate spacers 134, dielectric layer 175, etc.) (i.e., the etchant has a high etch selectivity with respect to the dielectric material having the first composition). The etching process is a dry etch, a wet etch, other suitable etch, or combinations thereof.

Incorporating the second sacrificial layers into fabrication of device 100 may increase thermal budget windows associated with fabrication thereof. For example, when sacrificial layers 115 are semiconductor layers, such as silicon germanium layers, temperatures implemented when forming source/drain structures 150A and/or source/drain structures 150B may be constrained to lower temperatures to avoid unwanted diffusion and/or mixing of constituents of sacrificial layers 115 (e.g., germanium) with semiconductor layers 120. Replacing sacrificial layers 115 with sacrificial oxide layers eliminates the intermixing concern (e.g., because such layers will not include germanium) and enables the use of higher temperatures, and thus broader temperature ranges, when forming source/drain structures 150A and/or source/drain structures 150B, thereby increasing process flexibility.

The present disclosure provides for many different embodiments. An exemplary method includes forming a source/drain recess, forming an insulator layer that partially fills the source/drain recess, treating the insulator layer with a nitrogen thermal treatment, and forming a doped semiconductor layer over the treated insulator layer. The insulator layer is formed in a bottom of the source/drain recess. The doped semiconductor layer fills a remainder of the source/drain recess. In some embodiments, the method includes treating the insulator layer with a silicon implantation process before forming the doped semiconductor layer. In some embodiments, the method includes tuning parameters of the nitrogen thermal treatment to increase the thickness of the insulator layer to at least 3 nm. In some embodiments, the method includes parameters of the nitrogen thermal treatment to reduce an etch rate of the insulator layer to a fluorine-based etchant. In some embodiments, the method includes forming an undoped semiconductor layer in the bottom of the source/drain recess before forming the insulator layer. In such embodiments, the insulator layer is formed over the undoped semiconductor layer, and the undoped semiconductor layer partially fills the source/drain recess.

In some embodiments, forming the insulator layer includes forming a nitride layer, and the nitrogen thermal treatment is an N₂ anneal. In some embodiments, the nitrogen thermal treatment is a first nitrogen thermal treatment, and the method further includes forming a metal oxide mask over the treated insulator layer, treating the metal oxide mask with a second nitrogen thermal treatment, and removing the metal oxide mask before forming the doped semiconductor layer. In some embodiments, forming the metal oxide mask includes forming an aluminum oxide mask, and the second nitrogen thermal treatment is an N₂ anneal. In some embodiments, the source/drain recess is in a first device region, and the method includes forming the metal oxide mask over a source/drain structure (which may be disposed in a second device region different than the first device region), removing the metal oxide mask from over the treated insulator layer before forming the doped semiconductor layer, and removing the metal oxide mask from over the source/drain structure after forming the doped semiconductor layer.

Another exemplary method includes forming a first source/drain recess in a first device region, forming a second source/drain recess in a second device region, forming a first source/drain structure in the first source/drain recess, and forming a second source/drain structure in the second source/drain recess. Forming the second source/drain structure includes forming an insulator layer in the second source/drain recess, forming a mask over the first source/drain structure after performing a first nitrogen thermal treatment on the insulator layer, and forming a doped semiconductor layer over the insulator layer after performing a second nitrogen thermal treatment on the mask. In some embodiments, the method includes performing a silicon implantation process on the insulator layer before forming the mask over the first source/drain structure. In some embodiments, performing the first nitrogen thermal treatment includes increasing a thickness of the insulator layer. In some embodiments, performing the first nitrogen thermal treatment includes performing a first N₂ anneal and performing the second nitrogen thermal treatment includes performing a second N₂ anneal.

In some embodiments, the first device region is a p-type transistor region, and the second device region is an n-type transistor region. In some embodiments, forming the mask includes depositing an aluminum oxide layer over the first source/drain structure in the first device region and the insulator layer in the second device region and removing the aluminum oxide layer from over the insulator layer in the second device region after performing the second nitrogen thermal treatment.

In some embodiments, the insulator layer is a first insulator layer, the first device region is unmasked when forming the first insulator layer, and the method includes forming a second insulator layer over the first source/drain structure when forming the first insulator layer. In some embodiments, the insulator is a first insulator, and the doped semiconductor layer is a first doped semiconductor layer. In such embodiments, forming the first source/drain structure may include forming a second insulator layer in the first source/drain recess, forming a second doped semiconductor layer over the second insulator layer, and no nitrogen thermal treatment is performed on the second insulator layer before forming the second doped semiconductor layer.

An exemplary device structure includes a first type transistor (e.g., a p-type transistor) and a second type transistor (e.g., an n-type transistor). The first type transistor includes a first source/drain structure having a first insulator layer and a first doped epitaxial layer disposed on the first insulator layer. The second type transistor includes a second source/drain structure having a second insulator layer and a second doped epitaxial layer disposed on the second insulator layer. A nitrogen concentration of the second insulator layer is greater than a nitrogen concentration of the first insulator layer, and a thickness of the second insulator layer is at least 3 nm. In some embodiments, the first source/drain structure further includes a third insulator layer, the first doped epitaxial layer is disposed between the third insulator layer and the first insulator layer, and a nitrogen concentration of the third insulator layer is greater than the nitrogen concentration of the first insulator layer. In some embodiments, a thickness of the third insulator layer is less than the thickness of the second insulator layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain recess;
forming an insulator layer that partially fills the source/drain recess, wherein the insulator layer is formed in a bottom of the source/drain recess;
treating the insulator layer with a nitrogen thermal treatment; and
forming a doped semiconductor layer over the treated insulator layer, wherein the doped semiconductor layer fills a remainder of the source/drain recess.

2. The method of claim 1, wherein:
the forming the insulator layer includes forming a nitride layer; and
the nitrogen thermal treatment is an N₂ anneal.

3. The method of claim 1, the method further including treating the insulator layer with a silicon implantation process before forming the doped semiconductor layer.

4. The method of claim 1, wherein the nitrogen thermal treatment is a first nitrogen thermal treatment, the method further comprising:
forming a metal oxide mask over the treated insulator layer;
treating the metal oxide mask with a second nitrogen thermal treatment; and
removing the metal oxide mask before forming the doped semiconductor layer.

5. The method of claim 4, wherein:
the source/drain recess is in a first device region; and
the method further includes:
forming the metal oxide mask over a source/drain structure, wherein the source/drain structure is in a second device region,
removing the metal oxide mask from over the treated insulator layer before forming the doped semiconductor layer, and
removing the metal oxide mask from over the source/drain structure after forming the doped semiconductor layer.

6. The method of claim 4, wherein:
the forming the metal oxide mask includes forming an aluminum oxide mask; and
the second nitrogen thermal treatment is an N₂ anneal.

7. The method of claim 1, further comprising tuning parameters of the nitrogen thermal treatment to increase the thickness of the insulator layer to at least 3 nm.

8. The method of claim 1, further comprising tuning parameters of the nitrogen thermal treatment to reduce an etch rate of the insulator layer to a fluorine-based etchant.

9. The method of claim 1, further comprising forming an undoped semiconductor layer in the bottom of the source/drain recess before forming the insulator layer, wherein the insulator layer is formed over the undoped semiconductor layer and the undoped semiconductor layer partially fills the source/drain recess.

10. A method comprising:
forming a first source/drain recess in a first device region;
forming a second source/drain recess in a second device region;
forming a first source/drain structure in the first source/drain recess; and
forming a second source/drain structure in the second source/drain recess, wherein the forming the second source/drain structure includes:
forming an insulator layer in the second source/drain recess,
after performing a first nitrogen thermal treatment on the insulator layer, forming a mask over the first source/drain structure, and
after performing a second nitrogen thermal treatment on the mask, forming a doped semiconductor layer over the insulator layer.

11. The method of claim 10, further comprising performing a silicon implantation process on the insulator layer before forming the mask over the first source/drain structure.

12. The method of claim 10, wherein the forming the mask includes:
depositing an aluminum oxide layer over the first source/drain structure in the first device region and the insulator layer in the second device region; and
removing the aluminum oxide layer from over the insulator layer in the second device region after performing the second nitrogen thermal treatment.

13. The method of claim 10, wherein the performing the first nitrogen thermal treatment includes increasing a thickness of the insulator layer.

14. The method of claim 10, wherein:
the insulator layer is a first insulator layer;
the first device region is unmasked when forming the first insulator layer; and
the method further includes forming a second insulator layer over the first source/drain structure when forming the first insulator layer.

15. The method of claim 10, wherein:
the insulator is a first insulator;
the doped semiconductor layer is a first doped semiconductor layer; and
the forming the first source/drain structure includes:
forming a second insulator layer in the first source/drain recess, and
forming a second doped semiconductor layer over the second insulator layer, wherein no nitrogen thermal treatment is performed on the second insulator layer before forming the second doped semiconductor layer.

16. The method of claim 10, wherein the performing the first nitrogen thermal treatment includes performing a first N₂ anneal and the performing the second nitrogen thermal treatment includes performing a second N₂ anneal.

17. The method of claim 10, wherein:
the first device region is a p-type transistor region;
the second device region is an n-type transistor region.

18. A device structure comprising:
a first type transistor that includes a first source/drain structure having a first insulator layer and a first doped epitaxial layer disposed on the first insulator layer;
a second type transistor that includes a second source/drain structure having a second insulator layer and a second doped epitaxial layer disposed on the second insulator layer, wherein a nitrogen concentration of the second insulator layer is greater than a nitrogen concentration of the first insulator layer; and
wherein a thickness of the second insulator layer is at least 3 nm.

19. The device structure of claim 18, wherein:
the first source/drain structure further includes a third insulator layer; and
the first doped epitaxial layer is disposed between the third insulator layer and the first insulator layer, wherein a nitrogen concentration of the third insulator layer is greater than the nitrogen concentration of the first insulator layer.

20. The device structure of claim 19, wherein a thickness of the third insulator layer is less than the thickness of the second insulator layer.
